(19) United States
(12) Patent Application Publication
(10) Pub. No.: US 2020/0083444 A1
(43) Pub. Date: Mar. 12, 2020

(54) VARIABLE RESISTANCE MEMORY DEVICE AND METHOD OF MANUFACTURING THE SAME

(71) Applicant: SAMSUNG ELECTRONICS CO., LTD., SUWON-SI (KR)

(72) Inventors: YONGJIN PARK, SEOUL (KR); JUNHWAN PARK, HWASEONG-SI (KR); DONGJUN SEONG, SEONGNAM-SI (KR); GYUHWAN OH, HWASEONG-SI (KR); HYUNGJONG JEONG, SEONGNAM-SI (KR)

(21) Appl. No.: 16/424,608

(22) Filed: May 29, 2019

(30) Foreign Application Priority Data
Sep. 6, 2018 (KR) 10-2018-0106430

(51) Int. Cl. H01L 45/00; H01L 27/24

(52) U.S. Cl. CPC H01L 45/126; H01L 27/2481; H01L 45/1233; H01L 45/06

(57) ABSTRACT

A variable resistance memory device includes a first conductive line disposed on a substrate, a second conductive line disposed on the first conductive line and intersecting the first conductive line, and a memory cell disposed between the first conductive line and the second conductive line. The memory cell includes a variable resistance pattern, and a heater electrode disposed on the variable resistance pattern. The heater electrode includes a through-hole penetrating the heater electrode. The through-hole exposes one surface of the variable resistance pattern.

### CROSS-REFERENCE TO RELATED APPLICATIONS

This application claims priority under 35 U.S.C. § 119 to Korean Patent Application No. 10-2018-0106430, filed on Sep. 6, 2018 in the Korean Intellectual Property Office, the disclosure of which is hereby incorporated by reference in its entirety.

### TECHNICAL FIELD

Exemplary embodiments of the present inventive concept relate to a semiconductor device and, more particularly, to a variable resistance memory device and a method of manufacturing the same.

### DISCUSSION OF THE RELATED ART

Semiconductor memory devices may be classified as volatile memory devices and non-volatile memory devices. A volatile memory device loses stored data when its power supply is interrupted. Examples of a volatile memory device include a dynamic random access memory (DRAM) device and a static random access memory (SRAM) device. A non-volatile memory device retains stored data even when its power supply is interrupted. Examples of a non-volatile memory device include programmable ROM (PROM), erasable PROM (EPROM), electrically EPROM (EEPROM), and a flash memory device.

Next-generation semiconductor memory devices such as, for example, magnetic random access memory (MRAM) devices and phase-change random access memory (PRAM) devices, have been developed to provide semiconductor memory devices having high performance and low power consumption. Materials of these next-generation semiconductor memory devices may have resistance values that are variable according to currents or voltages applied thereto, and may retain their resistance values even when currents or voltages are interrupted.

### SUMMARY

Exemplary embodiments of the present inventive concept provide a variable resistance memory device including a memory cell having a simplified structure, and a method of manufacturing the same.

Exemplary embodiments of the present inventive concept also provide a variable resistance memory device capable of being efficiently manufactured, and a method of manufacturing the same.

In an exemplary embodiment, a variable resistance memory device includes a first conductive line disposed on a substrate, a second conductive line disposed on the first conductive line and intersecting the first conductive line, and a memory cell disposed between the first conductive line and the second conductive line. The memory cell includes a variable resistance pattern, and a heater electrode disposed on the variable resistance pattern. The heater electrode includes a through-hole penetrating the heater electrode. The through-hole exposes one surface of the variable resistance pattern.

In an exemplary embodiment, a variable resistance memory device includes a first conductive line disposed on a substrate and extending in a first direction, a second conductive line disposed on the first conductive line and extending in a second direction intersecting the first direction, and a memory cell disposed between the first conductive line and the second conductive line and located at an intersecting point of the first conductive line and the second conductive line. The memory cell includes a variable resistance pattern, an insulating pattern disposed on a top surface of the variable resistance pattern, and a heater electrode disposed on the top surface of the variable resistance pattern and surrounding a sidewall of the insulating pattern.

In an exemplary embodiment, a variable resistance memory device includes a plurality of first conductive lines disposed on a substrate and extending in a first direction, a plurality of second conductive lines disposed on the first conductive lines and extending in a second direction intersecting the first direction, and a plurality of memory cells disposed between the first conductive lines and the second conductive lines, and disposed at intersecting points of the first conductive lines and the second conductive lines, respectively. Each of the memory cells includes a variable resistance pattern, and a heater electrode disposed on a top surface of the variable resistance pattern. The heater electrode has a pipe shape which extends from the top surface of the variable resistance pattern in a third direction substantially perpendicular to a top surface of the substrate.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a conceptual view illustrating a variable resistance memory device according to exemplary embodiments of the present inventive concept.

FIG. 2 is a perspective view schematically illustrating a variable resistance memory device according to exemplary embodiments of the present inventive concept.

FIG. 3 is a plan view illustrating a variable resistance memory device according to exemplary embodiments of the present inventive concept.

FIG. 4 is a cross-sectional view taken along lines I-I′ and II-II′ of FIG. 3.

FIGS. 5A and 5B are plan views illustrating an exemplary embodiment of a heater electrode of FIG. 4.

FIGS. 6A and 6B are plan views illustrating an exemplary embodiment of the heater electrode of FIG. 4.

FIGS. 7 to 14 are cross-sectional views corresponding to lines I-I′ and II-IF of FIG. 3, and illustrate a method of manufacturing a variable resistance memory device according to exemplary embodiments of the present inventive concept.

FIG. 15 is a cross-sectional view corresponding to lines I-I′ and II-IF of FIG. 3, and illustrate a variable resistance memory device according to exemplary embodiments of the present inventive concept.

FIGS. 16A and 16B are plan views illustrating an exemplary embodiment of a heater electrode of FIG. 15.

FIGS. 17A and 17B are plan views illustrating an exemplary embodiment of the heater electrode of FIG. 15.

FIGS. 18 to 20 are cross-sectional views corresponding to lines I-I′ and II-IF of FIG. 3, and illustrate a method of manufacturing a variable resistance memory device according to exemplary embodiments of the present inventive concept.

FIG. 21 is a cross-sectional view corresponding to lines I-I′ and II-IF of FIG. 3, and illustrate a variable resistance memory device according to exemplary embodiments of the present inventive concept.

FIGS. 22 to 24 are cross-sectional views corresponding to lines I-I′ and II-IF of FIG. 3, and illustrate a method of manufacturing a variable resistance memory device according to exemplary embodiments of the present inventive concept.

FIG. 25 is a perspective view schematically illustrating a variable resistance memory device according to exemplary embodiments of the present inventive concept.

FIG. 26 is a plan view illustrating a variable resistance memory device according to exemplary embodiments of the present inventive concept.

FIG. 27 is a cross-sectional view taken along lines I-I′ and II-IF of FIG. 26.

FIG. 28 is a plan view illustrating a variable resistance memory device according to exemplary embodiments of the present inventive concept.

FIG. 29 is a cross-sectional view taken along lines I-I′ and II-IF of FIG. 28.

### DETAILED DESCRIPTION OF THE EXEMPLARY EMBODIMENTS

Exemplary embodiments of the present inventive concept will be described more fully hereinafter with reference to the accompanying drawings. Like reference numerals may refer to like elements throughout the accompanying drawings.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. In addition, it will also be understood that when a layer is referred to as being “between” two layers, it can be the only layer between the two layers, or one or more intervening layers may also be present.

It will be understood that when a component, such as a film, a region, a layer, or an element, is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component.

It will be further understood that the terms “first,” “second,” “third,” etc. are used herein to distinguish one element from another, and the elements are not limited by these terms. Thus, a “first” element in an exemplary embodiment may be described as a “second” element in another exemplary embodiment.

It will be further understood that when two components or directions are described as extending substantially parallel or perpendicular to each other, the two components or directions extend exactly parallel or perpendicular to each other, or extend approximately parallel or perpendicular to each other within a measurement error as would be understood by a person having ordinary skill in the art. Similarly, when two components are described as being substantially aligned with each other or substantially coplanar with each other, it is to be understood that the two components are exactly aligned with each other or exactly coplanar with each other, or are approximately aligned with each other or approximately coplanar with each other within a measurement error as would be understood by a person having ordinary skill in the art.

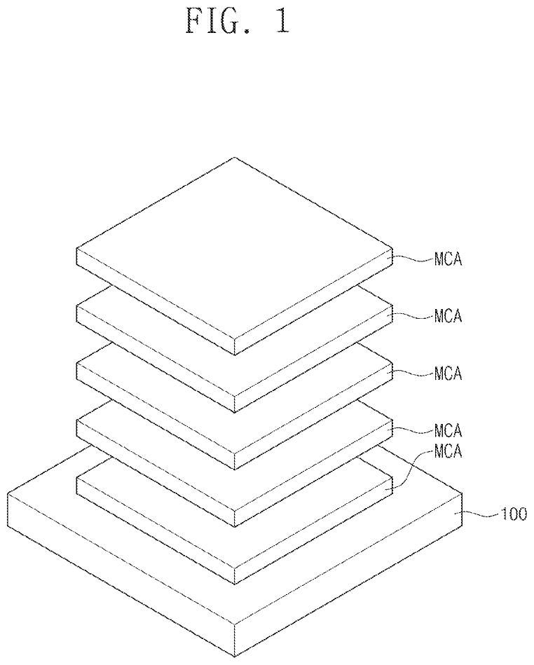

FIG. 1 is a conceptual view illustrating a variable resistance memory device according to exemplary embodiments of the present inventive concept.

Referring to FIG. 1, a variable resistance memory device may include a plurality of memory cell stacks MCA sequentially stacked on a substrate 100. Each of the memory cell stacks MCA may include a plurality of memory cells two-dimensionally arranged. The variable resistance memory device may also include conductive lines which are disposed between the memory cell stacks MCA, and which are used for write, read and/or erase operation of the memory cells. FIG. 1 illustrates five memory cell stacks MCA. However, exemplary embodiments of the present inventive concept are not limited thereto. For example, in exemplary embodiments, the variable resistance memory device may include four or less memory cell stacks MCA or six or more memory cell stacks MCA.

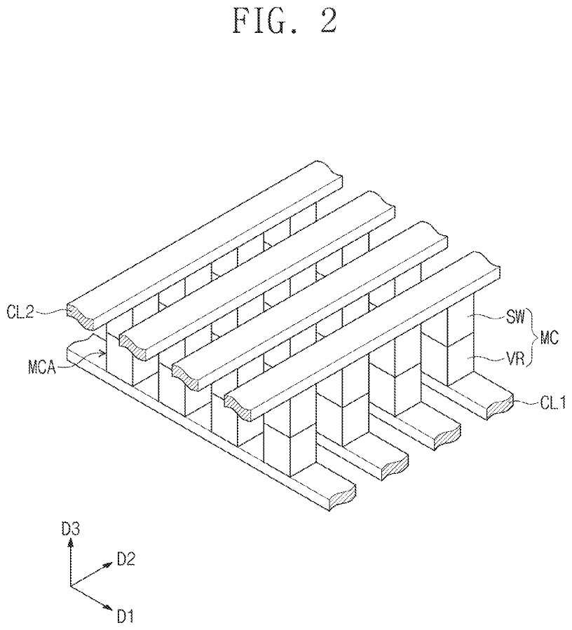

FIG. 2 is a perspective view schematically illustrating a variable resistance memory device according to exemplary embodiments of the present inventive concept. FIG. 2 illustrates one memory cell stack MCA as an example. However, exemplary embodiments of the present inventive concept are not limited thereto. For example, the structure of the one memory cell stack MCA illustrated in FIG. 2 may be applied to all of the memory cell stacks MCA illustrated in FIG. 1.

Referring to FIG. 2, first conductive lines CL1 and second conductive lines CL2 may be provided. The first conductive lines CL1 may extend in a first direction D1, and the second conductive lines CL2 may extend in a second direction D2 intersecting the first direction D1. The second conductive lines CL2 may be spaced apart from the first conductive lines CL1 in a third direction D3 substantially perpendicular to the first and second directions D1 and D2. The memory cell stack MCA may be provided between the first conductive lines CL1 and the second conductive lines CL2. The memory cell stack MCA may include memory cells MC that are provided at intersecting points of the first conductive lines CL1 and the second conductive lines CL2, respectively. The memory cells MC may be two-dimensionally arranged to constitute rows and columns.

Each of the memory cells MC may include a variable resistance pattern VR and a switching pattern SW. The variable resistance pattern VR and the switching pattern SW may be connected in series between a pair of the conductive lines CL1 and CL2 connected thereto. For example, the variable resistance pattern VR and the switching pattern SW included in each of the memory cells MC may be connected in series between a corresponding one of the first conductive lines CL1 and a corresponding one of the second conductive lines CL2. In FIG. 2, the switching pattern SW is provided on the variable resistance pattern VR. However, exemplary embodiments of the present inventive concept are not limited thereto. For example, in exemplary embodiments, the variable resistance pattern VR may be provided on the switching pattern SW, unlike FIG. 2.

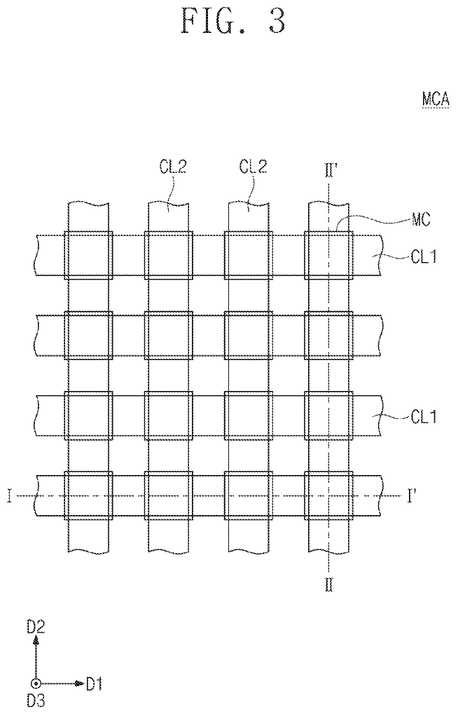

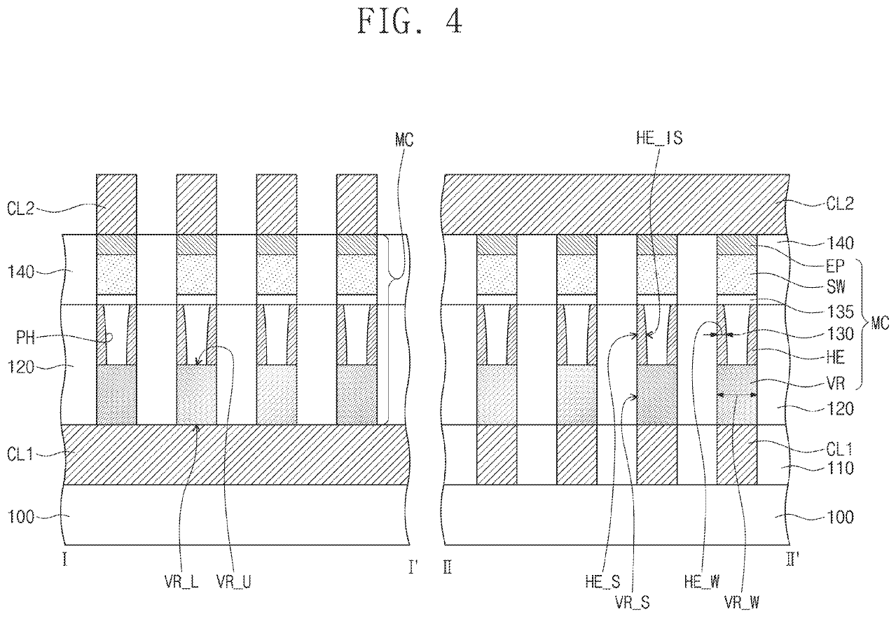

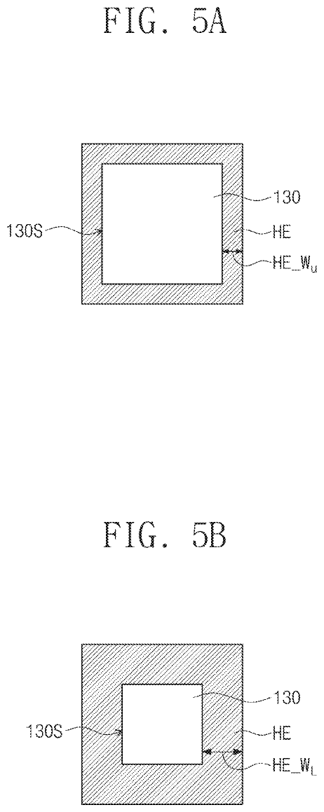

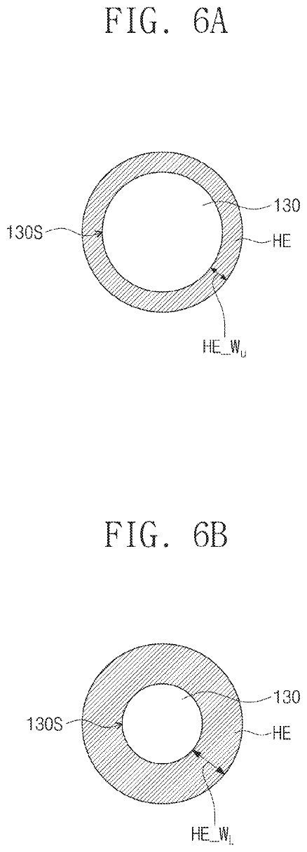

FIG. 3 is a plan view illustrating a variable resistance memory device according to exemplary embodiments of the present inventive concept. FIG. 4 is a cross-sectional view taken along lines I-I′ and II-IF of FIG. 3. FIGS. 5A and 5B are plan views illustrating an exemplary embodiment of a heater electrode of FIG. 4. FIGS. 6A and 6B are plan views illustrating an exemplary embodiment of the heater electrode of FIG. 4. A variable resistance memory device according to exemplary embodiments of the present inventive concept will be described based on one memory cell stack MCA for the purpose of ease and convenience of explanation.

Referring to FIGS. 3 and 4, first conductive lines CL1 and a first interlayer insulating layer 110 covering the first conductive lines CL1 may be disposed on the substrate 100. The first conductive lines CL1 may extend in the first direction D1 and may be spaced apart from each other in the second direction D2. The first conductive lines CL1 may be disposed in the first interlayer insulating layer 110, and the first interlayer insulating layer 110 may expose top surfaces of the first conductive lines CL1. The top surfaces of the first conductive lines CL1 may be substantially coplanar with a top surface of the first interlayer insulating layer 110. For example, the top surfaces of the first conductive lines CL1 may be substantially aligned with the top surface of the first interlayer insulating layer 110. The first conductive lines CL1 may include a metal (e.g., copper, tungsten, or aluminum) and/or a metal nitride (e.g., tantalum nitride, titanium nitride, or tungsten nitride). The first interlayer insulating layer 110 may include, for example, at least one of silicon oxide, silicon nitride, or silicon oxynitride.

Second conductive lines CL2 may be provided to intersect the first conductive lines CL1. The second conductive lines CL2 may extend in the second direction D2 and may be spaced apart from one another in the first direction D1. The second conductive lines CL2 may be spaced apart from the first conductive lines CL1 in the third direction D3. The second conductive lines CL2 may include a metal (e.g., copper, tungsten, or aluminum) and/or a metal nitride (e.g., tantalum nitride, titanium nitride, or tungsten nitride).

Memory cells MC may be disposed between the first conductive lines CL1 and the second conductive lines CL2, and may be located at intersecting points of the first conductive lines CL1 and the second conductive lines CL2, respectively. For example, as shown in FIG. 3, in a plan view, the memory cells MC are located in areas in which one of the first conductive lines CL1 and one of the second conductive lines CL2 are both disposed. The memory cells MC may be two-dimensionally arranged in the first direction D1 and the second direction D2. The memory cells MC may constitute one memory cell stack MCA. One memory cell stack MCA is illustrated for the purpose of ease and convenience of explanation and illustration. However, exemplary embodiments are not limited thereto. For example, in exemplary embodiments, a plurality of memory cell stacks MCA may be stacked on the substrate 100 in the third direction D3. In this case, structures corresponding to the first conductive lines CL1, the second conductive lines CL2 and the memory cells MC may be repeatedly stacked on the substrate 100.

Each of the memory cells MC may be provided between a corresponding one of the first conductive lines CL1 and a corresponding one of the second conductive lines CL2. Each of the memory cells MC may include a variable resistance pattern VR and a heater electrode HE disposed on the variable resistance pattern VR. In exemplary embodiments, the variable resistance pattern VR may have an island shape which is located locally at an intersecting point of the corresponding first conductive line CL1 and the corresponding second conductive line CL2. In exemplary embodiments, the variable resistance pattern VR may have a line shape extending in the first direction D1 or the second direction D2, unlike FIGS. 3 and 4. In this case, the variable resistance pattern VR may be shared by a plurality of the memory cells MC arranged in the first direction D1 or the second direction D2.

The variable resistance pattern VR may include a material capable of storing information (or data) using its resistance change. For example, the variable resistance pattern VR may include a material of which a phase is reversibly changeable between a crystalline state and an amorphous state by a temperature. For example, the variable resistance pattern VR may include a compound that includes at least one of Te or Se (e.g., chalcogen elements) and at least one of Ge, Sb, Bi, Pb, Sn, Ag, As, S, Si, In, Ti, Ga, P, O, or C. For example, the variable resistance pattern VR may include at least one of GeSbTe, GeTeAs, SbTeSe, GeTe, SbTe, SeTeSn, GeTeSe, SbSeBi, GeBiTe, GeTeTi, InSe, GaTeSe, or InSbTe. As another example, the variable resistance pattern VR may have a superlattice structure in which layers including Ge and layers not including Ge are alternately and repeatedly stacked (e.g., a structure in which GeTe layers and SbTe layers are alternately and repeatedly stacked).

In exemplary embodiments, the variable resistance pattern VR may include at least one of perovskite compounds or conductive metal oxides. For example, the variable resistance pattern VR may include at least one of niobium oxide, titanium oxide, nickel oxide, zirconium oxide, vanadium oxide, (Pr,Ca)MnO3 (PCMO), strontium-titanium oxide, barium-strontium-titanium oxide, strontium-zirconium oxide, barium-zirconium oxide, or barium-strontium-zirconium oxide. In other examples, the variable resistance pattern VR may have a double-layer structure of a conductive metal oxide layer and a tunnel insulating layer, or may have a triple-layer structure of a first conductive metal oxide layer, a tunnel insulating layer and a second conductive metal oxide layer. In this case, the tunnel insulating layer may include aluminum oxide, hafnium oxide, or silicon oxide.

The heater electrode HE may be disposed on a top surface VR_U of the variable resistance pattern VR. The heater electrode HE may be spaced apart from the corresponding first conductive line CL1 with the variable resistance pattern VR interposed therebetween. A bottom surface VR_L of the variable resistance pattern VR may be in contact with the corresponding first conductive line CL1. For example, in exemplary embodiments, the bottom surface VR_L may directly contact the corresponding first conductive line CL1.

The heater electrode HE may include a through-hole PH penetrating the heater electrode HE. The through-hole PH may expose a portion of the top surface VR_U of the variable resistance pattern VR. The heater electrode HE may have a hollow pipe shape which extends from the top surface VR_U of the variable resistance pattern VR in the third direction D3. A top end and a bottom end of the heater electrode HE may be opened. For example, the heater electrode HE may have a pipe shape of which a top end and a bottom end are opened. Thus, in an exemplary embodiment, the heater electrode HE having the pipe shape with opened top and bottom ends may surround the insulating pattern 130 having a pillar shape, which is described further below. The bottom end of the heater electrode HE may be in contact with the top surface VR_U of the variable resistance pattern VR. For example, in an exemplary embodiment, the bottom end of the heater electrode HE may directly contact the top surface VR_U of the variable resistance pattern VR. An outer sidewall HE_S of the heater electrode HE may be substantially aligned with a sidewall VR_S of the variable resistance pattern VR. For example, the outer sidewall HE_S of the heater electrode HE and the sidewall VR_S of the variable resistance pattern VR may form an even surface with each other. For example, in an exemplary embodiment, the outer sidewall HE_S of the heater electrode HE does not protrude above or extend below the sidewall VR_S of the variable resistance pattern VR. The heater electrode HE may function as a heater which heats the variable resistance pattern VR to change a phase of the variable resistance pattern VR. The heater electrode HE may include, for example, at least one of W, Ti, Al, Cu, C, CN, TiN, TiAlN, TiSiN, TiCN, WN, CoSiN, WSiN, TaN, TaCN, or TaSiN.

Each of the memory cells MC may further include an insulating pattern 130 filling the inside of the heater electrode HE. The insulating pattern 130 may be disposed in the through-hole PH of the heater electrode HE and may be in contact with the top surface VR_U of the variable resistance pattern VR. For example, in an exemplary embodiment, the insulating pattern 130 may directly contact the top surface VR_U of the variable resistance pattern VR. The insulating pattern 130 may have a pillar shape which extends from the top surface VR_U of the variable resistance pattern VR in the third direction D3. For example, in an exemplary embodiment, the insulating pattern 130 may be a solid, columnar structure extending from the top surface VR_U of the variable resistance pattern VR in the third direction D3. The insulating pattern 130 may be in contact with an inner sidewall HE IS of the heater electrode HE. For example, in an exemplary embodiment, the insulating pattern 130 may directly contact the inner sidewall HE IS of the heater electrode HE. The insulating pattern 130 may include an oxide, a nitride, and/or an oxynitride. The insulating pattern 130 may include, for example, silicon oxide. For example, as shown in FIG. 5, the insulating pattern 130 may be disposed on the variable resistance pattern VR, and may be disposed in the through-hole PH of the heater electrode HE.

FIGS. 5A and 6A are plan views illustrating the top end of the heater electrode HE according to exemplary embodiments, and FIGS. 5B and 6B are plan views illustrating the bottom end of the heater electrode HE according to exemplary embodiments. Referring to FIGS. 4, 5A, 5B, 6A and 6B, the heater electrode HE may surround a sidewall 130S of the insulating pattern 130. For example, the heater electrode HE may entirely surround the sidewall 130S of the insulating pattern 130. The heater electrode HE may have a ring shape surrounding the sidewall 130S of the insulating pattern 130 when viewed in a plan view. For example, the heater electrode HE may have a ring shape entirely surrounding the sidewall 130S of the insulating pattern 130 when viewed in a plan view. In exemplary embodiments, as illustrated in FIGS. 5A and 5B, the insulating pattern 130 may have a polygonal shape (e.g., a quadrilateral shape) in a plan view, and the heater electrode HE may have a polygonal ring shape (e.g., a quadrilateral ring shape) in a plan view. In exemplary embodiments, as illustrated in FIGS. 6A and 6B, the insulating pattern 130 may have a circular shape in a plan view, and the heater electrode HE may have a circular ring shape in a plan view.

When the heater electrode HE is described as having a ring shape, the heater electrode HE may be a continuous shape that entirely surrounds the sidewall 130S of the insulating pattern 130. In exemplary embodiments, the heater electrode HE may directly contact the sidewall 130S of the insulating pattern with no elements disposed therebetween.

The heater electrode HE may have a width HE_W in a direction substantially parallel to a top surface of the substrate 100. The width HE_W of the heater electrode HE may be a distance between the outer sidewall HE_S and the inner sidewall HE IS of the heater electrode HE. A width HE_W_{L} at the bottom end of the heater electrode HE may be greater than a width HE_W_{U} at the top end of the heater electrode HE, as shown in FIGS. 5A, 5B, 6A and 6B. The variable resistance pattern VR may have a width VR_W in a direction substantially parallel to the top surface of the substrate 100. The width VR_W of the variable resistance pattern VR may be greater than twice the width HE_W_{L} at the bottom end of the heater electrode HE.

Referring again to FIGS. 3 and 4, each of the memory cells MC may further include a switching pattern SW which is connected in series to the variable resistance pattern VR and the heater electrode HE between the corresponding first conductive line CL1 and the corresponding second conductive line CL2. In exemplary embodiments, the heater electrode HE and the insulating pattern 130 may be disposed between the variable resistance pattern VR and the switching pattern SW. In this case, the heater electrode HE and the insulating pattern 130 may prevent the variable resistance pattern VR from being in direct contact with the switching pattern SW, and the switching pattern SW may be electrically connected to the variable resistance pattern VR through the heater electrode HE. The variable resistance pattern VR may be disposed between the corresponding first conductive line CL1 and the heater electrode HE, and the switching pattern SW may be disposed between the corresponding second conductive line CL2 and the heater electrode HE.

In exemplary embodiments, the switching pattern SW may have an island shape which is located locally at the intersecting point of the corresponding first conductive line CL1 and the corresponding second conductive line CL2. In exemplary embodiments, the switching pattern SW may have a line shape extending in the first direction D1 or the second direction D2, unlike FIGS. 3 and 4. In this case, the switching pattern SW may be shared by a plurality of the memory cells MC arranged in the first direction D1 or the second direction D2.

The switching pattern SW may be an element based on a threshold switching phenomenon having a nonlinear I-V curve (e.g., an S-shaped I-V curve). For example, the switching pattern SW may be an ovonic threshold switch (OTS) element having a bi-directional characteristic. The switching pattern SW may have a phase transition temperature between crystalline and amorphous states, which is higher than that of the variable resistance pattern VR. Thus, when the variable resistance memory device according to exemplary embodiments of the present inventive concept is operated, a phase of the variable resistance pattern VR may be reversibly changeable between a crystalline state and an amorphous state, but the switching pattern SW may be maintained in a substantially amorphous state without a phase change. In the present specification, the term ‘substantially amorphous state’ may include an amorphous state and may also include a case in which a grain boundary or a crystallized portion locally exists in a portion of a component.

The switching pattern SW may include a chalcogenide material. The chalcogenide material may include a compound which includes a chalcogen element (e.g., Te and/or Se) and at least one of Ge, Sb, Bi, Al, Pb, Sn, Ag, As, S, Si, In, Ti, Ga, or P. For example, the chalcogenide material may include at least one of AsTe, AsSe, GeTe, SnTe, GeSe, SnTe, SnSe, ZnTe, AsTeSe, AsTeGe, AsSeGe, AsTeGeSe, AsSeGeSi, AsTeGeSi, AsTeGeS, AsTeGeSiIn, AsTeGeSiP, AsTeGeSiSbS, AsTeGeSiSbP, AsTeGeSeSb, AsTeGeSeSi, SeTeGeSi, GeSbTeSe, GeBiTeSe, GeAsSbSe, GeAsBiTe, or GeAsBiSe. In exemplary embodiments, the switching pattern SW may further include an impurity such as, for example, at least one of C, N, B, or O.

Each of the memory cells MC may further include a barrier pattern 135 disposed between the switching pattern SW and the heater electrode HE. The barrier pattern 135 may extend between the switching pattern SW and the insulating pattern 130. The barrier pattern 135 may have conductivity, and thus, the switching pattern SW may be electrically connected to the heater electrode HE and the variable resistance pattern VR through the barrier pattern 135. In exemplary embodiments, the barrier pattern 135 may prevent the heater electrode HE from being in direct contact with the switching pattern SW. The barrier pattern 135 may include, for example, carbon.

Each of the memory cells MC may further include a connection electrode EP disposed between the switching pattern SW and the corresponding second conductive line CL2. The switching pattern SW may be electrically connected to the corresponding second conductive line CL2 through the connection electrode EP. The connection electrode EP may be spaced apart from the heater electrode HE with the switching pattern SW interposed therebetween. In exemplary embodiments, the connection electrode EP may have an island shape which is located locally at the intersecting point of the corresponding first conductive line CL1 and the corresponding second conductive line CL2. In this case, the connection electrodes EP respectively included in the memory cells MC may be provided at the intersecting points of the first conductive lines CL1 and the second conductive lines CL2, respectively, and thus, may be two-dimensionally arranged on the substrate 100. In exemplary embodiments, the connection electrode EP may have a line shape extending in the extending direction (e.g., the second direction D2) of the corresponding second conductive line CL2, unlike FIGS. 3 and 4. In this case, the connection electrode EP may be shared by a plurality of the memory cells MC arranged in the extending direction (e.g., the second direction D2) of the corresponding second conductive line CL2. The connection electrode EP may include, for example, at least one of W, Ti, Al, Cu, C, CN, TiN, TiAlN, TiSiN, TiCN, WN, CoSiN, WSiN, TaN, TaCN, TaSiN, or TiO.

A second interlayer insulating layer 120 may be disposed on the first interlayer insulating layer 110 and may cover the top surfaces of the first conductive lines CL1. The variable resistance pattern VR, the heater electrode HE and the insulating pattern 130 of each of the memory cells MC may be disposed in the second interlayer insulating layer 120. The second interlayer insulating layer 120 may cover the sidewall VR_S of the variable resistance pattern VR and the outer sidewall HE_S of the heater electrode HE. A third interlayer insulating layer 140 may be disposed on the second interlayer insulating layer 120. The barrier pattern 135, the switching pattern SW and the connection electrode EP of each of the memory cells MC may be disposed in the third interlayer insulating layer 140. The second conductive lines CL2 may be disposed on the third interlayer insulating layer 140. The second and third interlayer insulating layers 120 and 140 may include, for example, at least one of silicon oxide, silicon nitride, or silicon oxynitride.

According to exemplary embodiments of the present inventive concept, the heater electrode HE may prevent the switching pattern SW from being in direct contact with the variable resistance pattern VR, and may also function as a heating element that heats the variable resistance pattern VR for the phase change of the variable resistance pattern VR. In this case, in an exemplary embodiment, an additional electrode for heating the variable resistance pattern VR is not required between the variable resistance pattern VR and the corresponding first conductive line CL1, since the heater electrode HE functions as the heating element. Thus, exemplary embodiments provide a variable resistance memory device in which a structure of each of the memory cells MC is simplified.

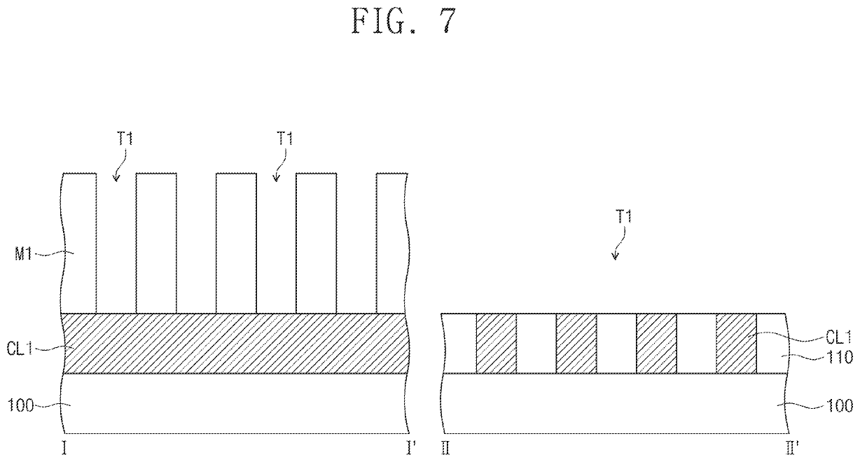

FIGS. 7 to 14 are cross-sectional views corresponding to lines I-I′ and II-IF of FIG. 3, and illustrate a method of manufacturing a variable resistance memory device according to exemplary embodiments of the present inventive concept. For convenience of explanation, a further description of elements and technical features previously described with reference to FIGS. 3, 4, 5A, 5B, 6A and 6B may be omitted.

Referring to FIGS. 3 and 7, the first conductive lines CL1 and the first interlayer insulating layer 110 covering the first conductive lines CL1 may be formed on the substrate 100. The first conductive lines CL1 may extend in the first direction D1 and may be spaced apart from one another in the second direction D2. The formation of the first conductive lines CL1 may include, for example, forming a conductive layer on the substrate 100 and patterning the conductive layer. The formation of the first interlayer insulating layer 110 may include, for example, forming an insulating layer covering the first conductive lines CL1 on the substrate 100, and planarizing the insulating layer to expose top surfaces of the first conductive lines CL1.

A first mold layer M1 may be formed on the first interlayer insulating layer 110 and the top surfaces of the first conductive lines CL1. The first mold layer M1 may include, for example, silicon nitride. First trenches T1 may be formed in the first mold layer M1. The first trenches T1 may be formed to intersect the first conductive lines CL1. The first trenches T1 may extend in the second direction D2 and may be spaced apart from one another in the first direction D1. Each of the first trenches T1 may expose portions of the top surfaces of the first conductive lines CL1 and portions of a top surface of the first interlayer insulating layer 110, which are alternately arranged in the second direction D2.

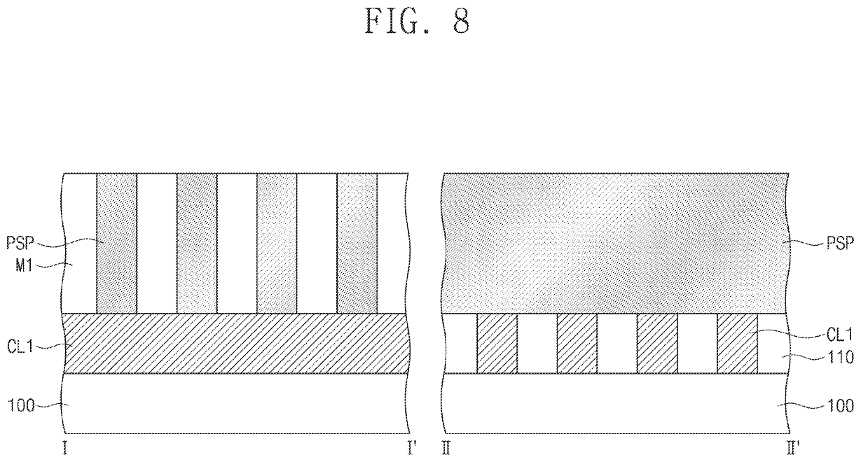

Referring to FIGS. 3 and 8, preliminary sacrificial patterns PSP may be formed in the first trenches T1, respectively. The formation of the preliminary sacrificial patterns PSP may include forming a sacrificial layer filling the first trenches T1 on the first mold layer M1, and planarizing the sacrificial layer until a top surface of the first mold layer M1 is exposed. The sacrificial layer may be formed by performing, for example, a chemical vapor deposition (CVD) process. The preliminary sacrificial patterns PSP may include a material having an etch selectivity with respect to the first mold layer M1. For example, in exemplary embodiments, the etch rates of the materials used to form the preliminary sacrificial patterns PSP and the first mold layer M1 may be related to each other such that the preliminary sacrificial patterns PSP and the first mold layer M1 are not etched in the same manner during an etching process. The preliminary sacrificial patterns PSP may include, for example, silicon oxide. The preliminary sacrificial patterns PSP may fill the first trenches T1, respectively. The preliminary sacrificial patterns PSP may extend in the second direction D2 and may be spaced apart from one another in the first direction D1.

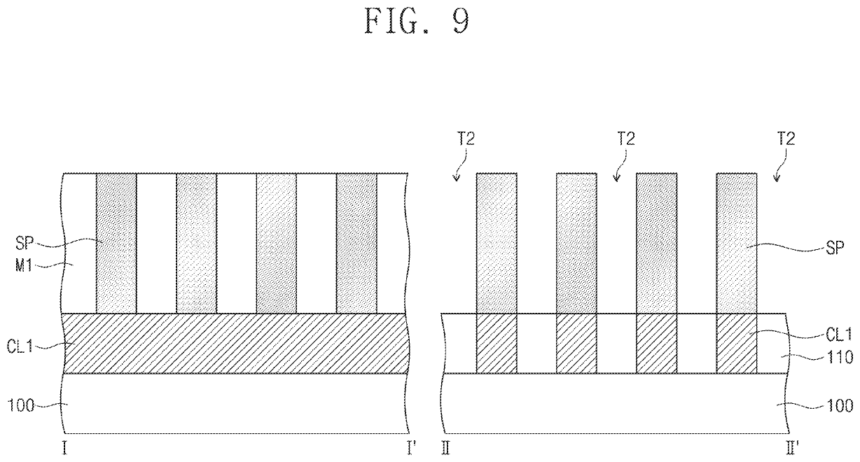

Referring to FIGS. 3 and 9, second trenches T2 may be formed in the first mold layer M1. The second trenches T2 may be formed to intersect the first trenches T1. The second trenches T2 may extend in the first direction D1 and may be spaced apart from one another in the second direction D2. Each of the second trenches T2 may expose the top surface of the first interlayer insulating layer 110 between the first conductive lines CL1. The formation of the second trenches T2 may include patterning the first mold layer M1 and the preliminary sacrificial patterns PSP. As a result of forming the second trenches T2, each of the preliminary sacrificial patterns PSP may be divided into a plurality of sacrificial patterns SP spaced apart from one another in the second direction D2. The plurality of sacrificial patterns SP may define regions in which memory cells to be described later will be formed. Each of the sacrificial patterns SP may be formed on the top surface of a corresponding one of the first conductive lines CL1.

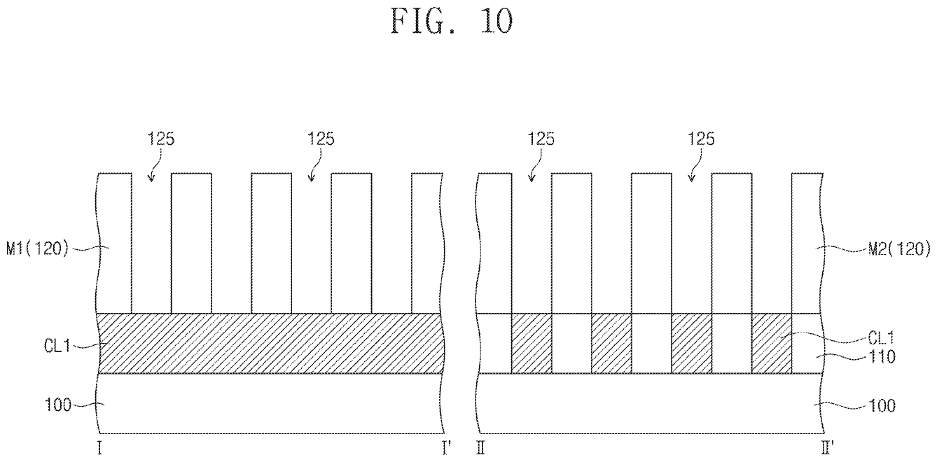

Referring to FIGS. 3 and 10, a second mold layer M2 may be formed to fill the second trenches T2. The second mold layer M2 may include the same insulating material as the first mold layer M1. For example, the second mold layer M2 may include silicon nitride. The first mold layer M1 and the second mold layer M2 may constitute the second interlayer insulating layer 120. Thereafter, the sacrificial patterns SP may be removed. The removal of the sacrificial patterns SP may include selectively etching the sacrificial patterns SP with respect to the second interlayer insulating layer 120. The sacrificial patterns SP may be selectively etched by, for example, a wet etching process. A plurality of gap regions 125 may be formed in the second interlayer insulating layer 120 as a result of the removal of the sacrificial patterns SP. Each of the gap regions 125 may expose the top surface of a corresponding one of the first conductive lines CL1.

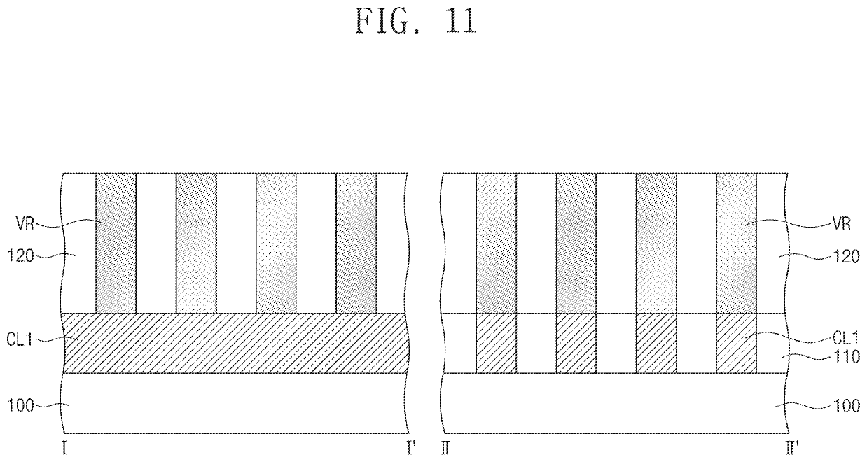

Referring to FIGS. 3 and 11, the variable resistance patterns VR may be formed in the gap regions 125, respectively. The variable resistance patterns VR may be formed to fill the gap regions 125, respectively. In exemplary embodiments, the formation of the variable resistance patterns VR may include forming a variable resistance layer filling the gap regions 125 on the second interlayer insulating layer 120, and planarizing the variable resistance layer until a top surface of the second interlayer insulating layer 120 is exposed.

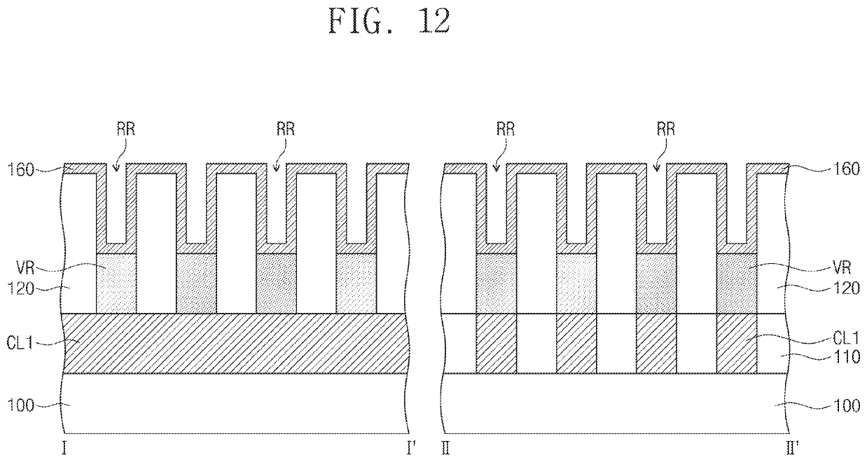

Referring to FIGS. 3 and 12, upper portions of the variable resistance patterns VR may be removed to form recess regions RR in the second interlayer insulating layer 120. The removal of the upper portions of the variable resistance patterns VR may include etching the upper portions of the variable resistance patterns VR until the variable resistance pattern VR having a desired thickness remains in each of the gap regions 125. Each of the recess regions RR may expose an inner sidewall of the second interlayer insulating layer 120 and a top surface of each of the variable resistance patterns VR. A heater electrode layer 160 may be formed on the second interlayer insulating layer 120 to partially fill each of the recess regions RR. The heater electrode layer 160 may cover inner surfaces of the recess regions RR with a substantially uniform thickness. For example, the thickness of the heater electrode layer 160 disposed on the inner surface of each of the recess regions RR may be substantially the same. The heater electrode layer 160 may be formed by, for example, an atomic layer deposition (ALD) process.

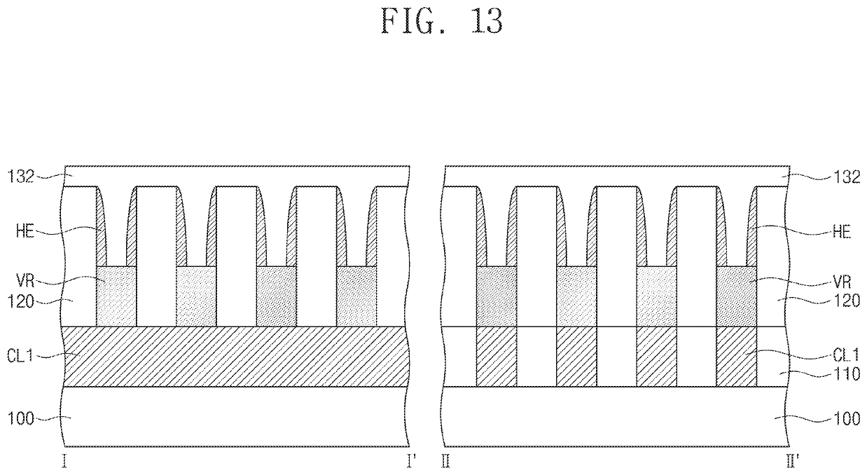

Referring to FIGS. 3 and 13, the heater electrode layer 160 may be anisotropically etched to form the heater electrodes HE in the recess regions RR, respectively. Each of the heater electrodes HE may be formed on an inner sidewall of each of the recess regions RR. The top surface of the second interlayer insulating layer 120 and portions of the top surfaces of the variable resistance patterns VR may be exposed by the anisotropic etching process. Each of the heater electrodes HE may have a spacer shape covering the inner sidewall of each of the recess regions RR when viewed in a cross-sectional view. Each of the heater electrodes HE may have a pipe shape of which a top end and a bottom end are opened. An insulating layer 132 may be formed on the second interlayer insulating layer 120 to fill a remaining portion of each of the recess regions RR. The insulating layer 132 may fill an inside of each of the heater electrodes HE.

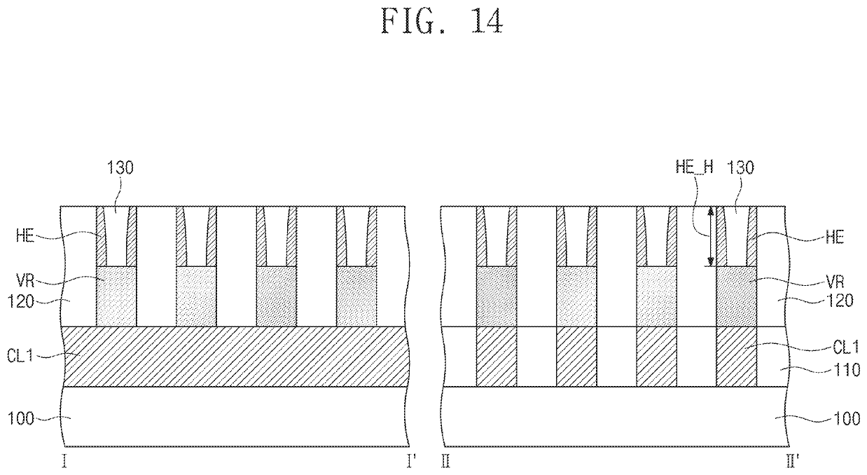

Referring to FIGS. 3 and 14, the insulating layer 132 may be planarized until the second interlayer insulating layer 120 is exposed. As a result, the insulating patterns 130 may be formed in the recess regions RR, respectively. When the insulating layer 132 is planarized, an upper portion of the second interlayer insulating layer 120 and upper portions of the heater electrodes HE may also be planarized. The planarization process may include, for example, an etch-back process.

According to exemplary embodiments of the present inventive concept, the heater electrode layer 160 may be formed on the variable resistance patterns VR, and then, the anisotropic etching process may be performed on the heater electrode layer 160 to form the heater electrodes HE. In this case, a height HE_H of each of the heater electrodes HE may be efficiently and accurately controlled during the anisotropic etching process. In addition, the first trenches T1 may be filled with the preliminary sacrificial patterns PSP, and the second trenches T2 may be formed by etching the first mold layer M1 and the preliminary sacrificial patterns PSP in the first mold layer M1. For example, according to exemplary embodiments, during the etching process for forming the second trenches T2, it is not required to etch a different kind of a material (e.g., a metal material) except insulating materials of the first mold layer M1 and the preliminary sacrificial patterns PSP. In this case, recessing of the first interlayer insulating layer 110 exposed by the first and second trenches T1 and T2 may be efficiently and accurately controlled.

Thus, according to exemplary embodiments of the present inventive concept, a variable resistance memory device may be efficiently manufactured.

Referring again to FIGS. 3 and 4, the switching patterns SW may be formed on the heater electrodes HE, respectively, and the barrier patterns 135 may be formed between the switching patterns SW and the heater electrodes HE. Each of the barrier patterns 135 may be disposed between each of the switching patterns SW and each of the heater electrodes HE. The connection electrodes EP may be formed on the switching patterns SW, respectively. In exemplary embodiments, the formation of the barrier patterns 135, the switching patterns SW and the connection electrodes EP may include sequentially forming a barrier layer, a switching layer, and a connection electrode layer on the second interlayer insulating layer 120, and sequentially etching the connection electrode layer, the switching layer, and the barrier layer. The third interlayer insulating layer 140 may be formed on the second interlayer insulating layer 120 after the formation of the barrier patterns 135, the switching patterns SW, and the connection electrodes EP. The third interlayer insulating layer 140 may be formed to cover the barrier patterns 135, the switching patterns SW, and the connection electrodes EP. The variable resistance patterns VR, the heater electrodes HE, the insulating patterns 130, the barrier patterns 135, the switching patterns SW, and the connection electrodes EP may constitute the memory cells MC.

The second conductive lines CL2 may be formed on the third interlayer insulating layer 140. The second conductive lines CL2 may be formed to intersect the first conductive lines CL1. The second conductive lines CL2 may extend in the second direction D2 and may be spaced apart from one another in the first direction D1. The second conductive lines CL2 may be formed by substantially the same method as the first conductive lines CL1.

According to exemplary embodiments of the present inventive concept, upper patterns (e.g., the barrier patterns 135, the switching patterns SW and the connection electrodes EP) may be formed on the heater electrodes HE and the insulating patterns 130. In this case, even though misalignment may occur between the upper patterns and the heater electrodes HE, the heater electrodes HE and the insulating patterns 130 may prevent the variable resistance patterns VR from being damaged during the etching process for forming the upper patterns. Thus, according to exemplary embodiments, a misalignment margin between the upper patterns and the heater electrodes HE may be efficiently and accurately secured. As a result, the variable resistance memory device may be efficiently manufactured.

When the variable resistance memory device according to exemplary embodiments of the present inventive concept includes a plurality of memory cell stacks MCA, the processes for forming the first conductive lines CL1, the memory cells MC, and the second conductive lines CL2 may be repeatedly performed.

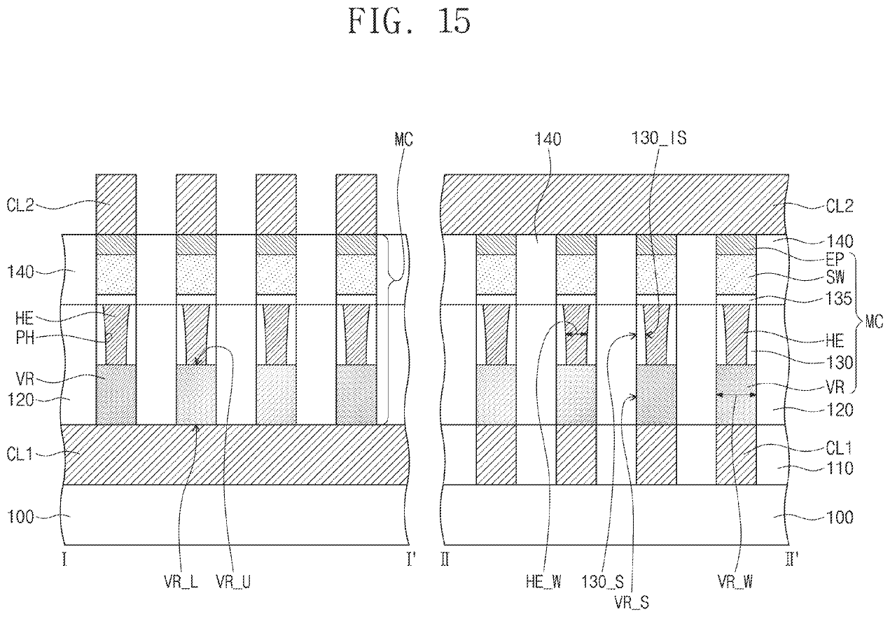

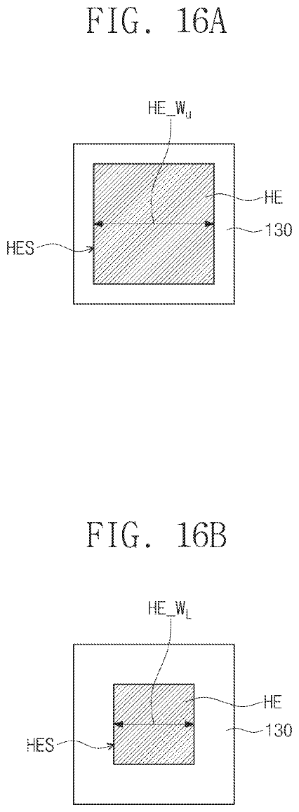

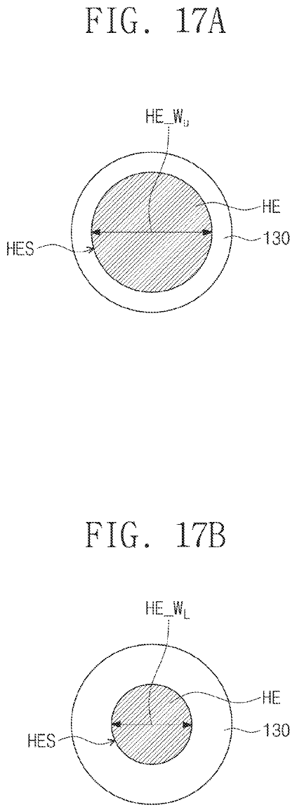

FIG. 15 is a cross-sectional view corresponding to lines I-I′ and II-IF of FIG. 3, and illustrate a variable resistance memory device according to exemplary embodiments of the present inventive concept. FIGS. 16A and 16B are plan views illustrating an exemplary embodiment of a heater electrode of FIG. 15. FIGS. 17A and 17B are plan views illustrating an exemplary embodiment of the heater electrode of FIG. 15. Hereinafter, for convenience of explanation, differences between the exemplary embodiments described herein and the exemplary embodiments previously described with reference to FIGS. 3, 4, 5A, 5B, 6A and 6B will be mainly described, and a further description of elements and technical features previously described may be omitted.

Referring to FIGS. 3 and 15, each of the memory cells MC may include the variable resistance pattern VR and the heater electrode HE disposed on the variable resistance pattern VR. The bottom surface VR_L of the variable resistance pattern VR may be in contact with a corresponding one of the first conductive lines CL1, and the heater electrode HE may be disposed on the top surface VR_U of the variable resistance pattern VR. The heater electrode HE may be spaced apart from the corresponding first conductive line CL1 with the variable resistance pattern VR interposed therebetween. The heater electrode HE may have a pillar shape which extends from the top surface VR_U of the variable resistance pattern VR in the third direction D3.

Each of the memory cells MC may further include the insulating pattern 130 disposed on the top surface VR_U of the variable resistance pattern VR. The insulating pattern 130 may include the through-hole PH penetrating the insulating pattern 130, and the through-hole PH may expose a portion of the top surface VR_U of the variable resistance pattern VR. The heater electrode HE may be disposed in the through-hole PH of the insulating pattern 130 and may be in contact with the top surface VR_U of the variable resistance pattern VR.

The insulating pattern 130 may have a hollow pipe shape which extends from the top surface VR_U of the variable resistance pattern VR in the third direction D3. A top end and a bottom end of the insulating pattern 130 may be opened. For example, the insulating pattern 130 may have a pipe shape of which a top end and a bottom end are opened. A bottom end of the insulating pattern 130 may be in contact with the top surface VR_U of the variable resistance pattern VR. An outer sidewall 130_S of the insulating pattern 130 may be substantially aligned with the sidewall VR_S of the variable resistance pattern VR. The heater electrode HE may be in contact with an inner sidewall 130_IS of the insulating pattern 130.

FIGS. 16A and 17A are plan views illustrating a top end of the heater electrode HE according to exemplary embodiments, and FIGS. 16B and 17B are plan views illustrating a bottom end of the heater electrode HE according to exemplary embodiments. Referring to FIGS. 15, 16A, 16B, 17A and 17B, the insulating pattern 130 may surround a sidewall HES of the heater electrode HE. For example, the insulating pattern 130 may entirely surround the sidewall HES of the heater electrode HE. The insulating pattern 130 may have a ring shape surrounding the sidewall HES of the heater electrode HE when viewed in a plan view. For example, the insulating pattern 130 may have a ring shape entirely surrounding the sidewall HES of the heater electrode HE when viewed in a plan view. In exemplary embodiments, as illustrated in FIGS. 16A and 16B, the heater electrode HE may have a polygonal shape (e.g., a quadrilateral shape) in a plan view, and the insulating pattern 130 may have a polygonal ring shape (e.g., a quadrilateral ring shape) in a plan view. In exemplary embodiments, as illustrated in FIGS. 17A and 17B, the heater electrode HE may have a circular shape in a plan view, and the insulating pattern 130 may have a circular ring shape in a plan view.

The heater electrode HE may have a width HE_W in a direction substantially parallel to the top surface of the substrate 100. A width HE_W_{L} at the bottom end of the heater electrode HE may be less than a width HE_W_{U} at the top end of the heater electrode HE. The variable resistance pattern VR may have a width VR_W in a direction substantially parallel to the top surface of the substrate 100. The width VR_W of the variable resistance pattern VR may be greater than the width HE_W of the heater electrode HE. For example, the width VR_W of the variable resistance pattern VR may be greater than the width HE_W_{L} at the bottom end of the heater electrode HE and the width HE_W_{U} at the top end of the heater electrode HE.

Referring again to FIGS. 3 and 15, the second interlayer insulating layer 120 may be disposed on the first interlayer insulating layer 110 and may cover the top surfaces of the first conductive lines CL1. The variable resistance pattern VR, the heater electrode HE and the insulating pattern 130 of each of the memory cells MC may be disposed in the second interlayer insulating layer 120. The second interlayer insulating layer 120 may cover the sidewall VR_S of the variable resistance pattern VR and the outer sidewall 130_S of the insulating pattern 130.

Except for the differences described above, other components and/or features of the variable resistance memory device described herein may be substantially the same as corresponding components and/or features of the variable resistance memory device described above with reference to FIGS. 3, 4, 5A, 5B, 6A and 6B.

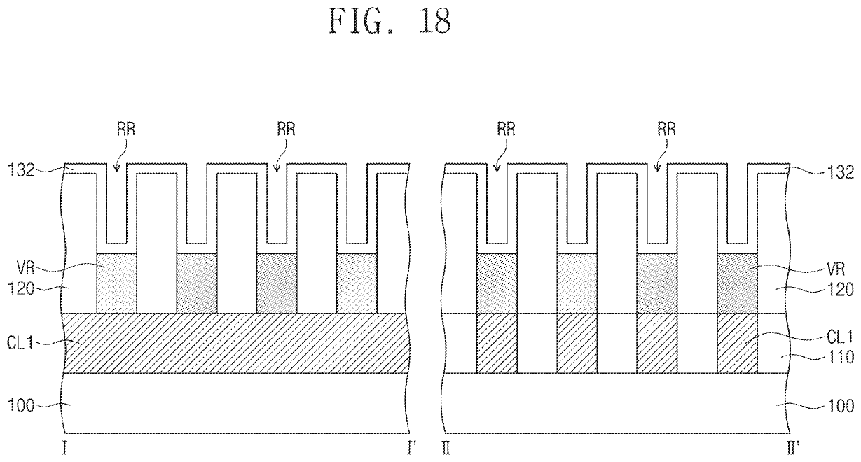

FIGS. 18 to 20 are cross-sectional views corresponding to lines I-I′ and II-II′ of FIG. 3, and illustrate a method of manufacturing a variable resistance memory device according to exemplary embodiments of the present inventive concept. Hereinafter, for convenience of explanation, differences between the exemplary embodiments described herein and the exemplary embodiments previously described with reference to FIGS. 7 to 14 will be mainly described, and a further description of elements and technical features previously described may be omitted.

As described above with reference to FIGS. 7 to 11, the first conductive lines CL1 and the first interlayer insulating layer 110 covering the first conductive lines CL1 may be formed on the substrate 100. The first mold layer M1 may be formed on the first interlayer insulating layer 110, and the first trenches T1 may be formed in the first mold layer M1. The preliminary sacrificial patterns PSP may be formed in the first trenches T1, respectively, and the second trenches T2 may be formed to intersect the first trenches T1. The second trenches T2 may be formed by patterning the first mold layer M1 and the preliminary sacrificial patterns PSP. As a result of forming the second trenches T2, each of the preliminary sacrificial patterns PSP may be divided into the plurality of sacrificial patterns SP spaced apart from one another in the second direction D2. The second mold layer M2 may be formed to fill the second trenches T2. The first mold layer M1 and the second mold layer M2 may constitute the second interlayer insulating layer 120. The plurality of gap regions 125 may be formed in the second interlayer insulating layer 120 by removing the sacrificial patterns SP. The variable resistance patterns VR may be formed in the gap regions 125, respectively.

Referring to FIGS. 3 and 18, upper portions of the variable resistance patterns VR may be removed to form the recess regions RR in the second interlayer insulating layer 120. Each of the recess regions RR may expose an inner sidewall of the second interlayer insulating layer 120 and a top surface of each of the variable resistance patterns VR. According to exemplary embodiments, the insulating layer 132 may be formed on the second interlayer insulating layer 120 to partially fill each of the recess regions RR. The insulating layer 132 may cover inner surfaces of the recess regions RR with a substantially uniform thickness. For example, the thickness of the insulating layer 132 that covers the inner surface of each of the recess regions RR may be substantially the same.

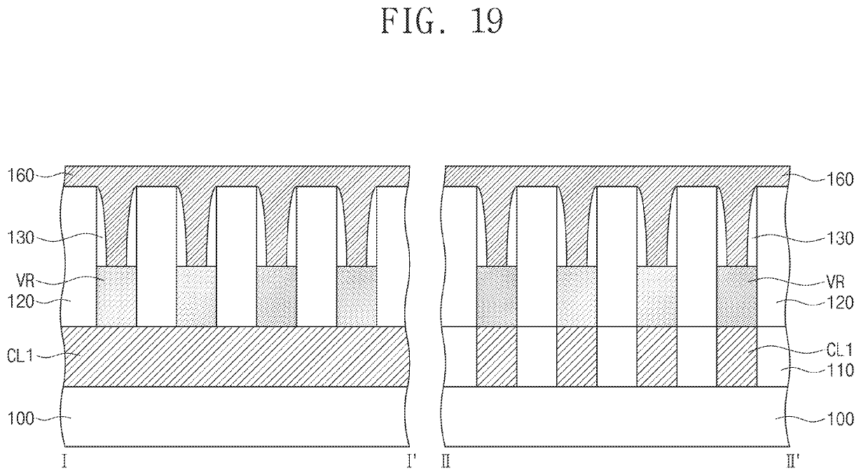

Referring to FIGS. 3 and 19, the insulating layer 132 may be anisotropically etched to form the insulating patterns 130 in the recess regions RR, respectively. Each of the insulating patterns 130 may be formed on an inner sidewall of each of the recess regions RR. The top surface of the second interlayer insulating layer 120 and portions of the top surfaces of the variable resistance patterns VR may be exposed by the anisotropic etching process. Each of the insulating patterns 130 may have a spacer shape covering the inner sidewall of each of the recess regions RR when viewed in a cross-sectional view. Each of the insulating patterns 130 may have a pipe shape of which a top end and a bottom end are opened. The heater electrode layer 160 may be formed on the second interlayer insulating layer 120 to fill a remaining portion of each of the recess regions RR. The heater electrode layer 160 may fill an inside of each of the insulating patterns 130.

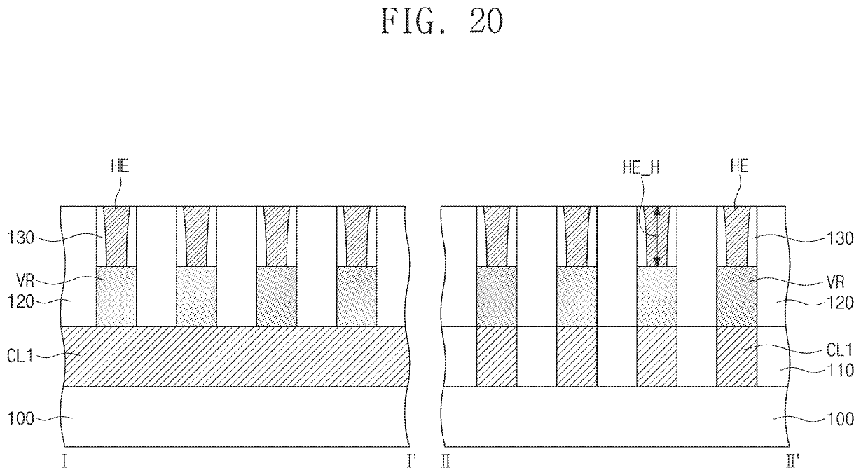

Referring to FIGS. 3 and 20, the heater electrode layer 160 may be planarized until the second interlayer insulating layer 120 is exposed. As a result, heater electrodes HE may be formed in the recess regions RR, respectively. When the heater electrode layer 160 is planarized, an upper portion of the second interlayer insulating layer 120 and upper portions of the insulating patterns 130 may also be planarized. The planarization process may include, for example, an etch-back process.

According to exemplary embodiments, the heater electrode layer 160 may be formed to fill the insides of the insulating patterns 130, and then, the planarization process may be performed on the heater electrode layer 160 to form the heater electrodes HE. In this case, the height HE_H of each of the heater electrodes HE may be efficiently and accurately controlled during the planarization process.

Except for the differences described above, other processes and/or features of the manufacturing method described herein may be substantially the same as corresponding processes and/or features of the manufacturing method described above with reference to FIGS. 7 to 14.

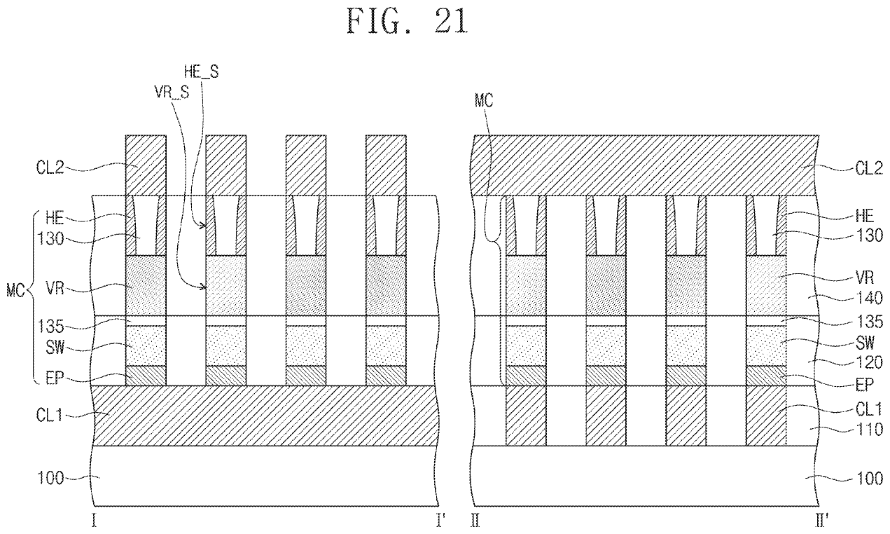

FIG. 21 is a cross-sectional view corresponding to lines I-I′ and II-IF of FIG. 3, and illustrate a variable resistance memory device according to exemplary embodiments of the present inventive concept. Hereinafter, for convenience of explanation, differences between the exemplary embodiments previously described with reference to FIGS. 3, 4, 5A, 5B, 6A and 6B will be mainly described, and a further description of elements and technical features previously described may be omitted.

Referring to FIGS. 3 and 21, according to exemplary embodiments, the switching pattern SW may be disposed between the corresponding first conductive line CL1 and the variable resistance pattern VR, and the variable resistance pattern VR may be disposed between the corresponding second conductive line CL2 and the switching pattern SW. The connection electrode EP may be disposed between the switching pattern SW and the corresponding first conductive line CL1, and the barrier pattern 135 may be disposed between the switching pattern SW and the variable resistance pattern VR. The heater electrode HE and the insulating pattern 130 may be disposed between the variable resistance pattern VR and the corresponding second conductive line CL2. According to exemplary embodiments, the barrier pattern 135 may prevent the switching pattern SW from being in direct contact with the variable resistance pattern VR, and the heater electrode HE may function as a heating element that heats the variable resistance pattern VR for the phase change of the variable resistance pattern VR.

The second interlayer insulating layer 120 may be disposed on the first interlayer insulating layer 110 and may cover the top surfaces of the first conductive lines CL1. The connection electrode EP, the switching pattern SW and the barrier pattern 135 of each of the memory cells MC may be disposed in the second interlayer insulating layer 120. The third interlayer insulating layer 140 may be disposed on the second interlayer insulating layer 120. The variable resistance pattern VR, the heater electrode HE and the insulating pattern 130 of each of the memory cells MC may be disposed in the third interlayer insulating layer 140. The third interlayer insulating layer 140 may cover the sidewall VR_S of the variable resistance pattern VR and the outer sidewall HE_S of the heater electrode HE.

Except for the relative positions of the connection electrode EP, the switching pattern SW, the barrier pattern 135, the variable resistance pattern VR, the heater electrode HE, and the insulating pattern 130 in each of the memory cells MC, other components and features of the variable resistance memory device according to exemplary embodiments described herein may be substantially the same as corresponding components and features of the variable resistance memory device described with reference to FIGS. 3, 4, 5A, 5B, 6A and 6B.

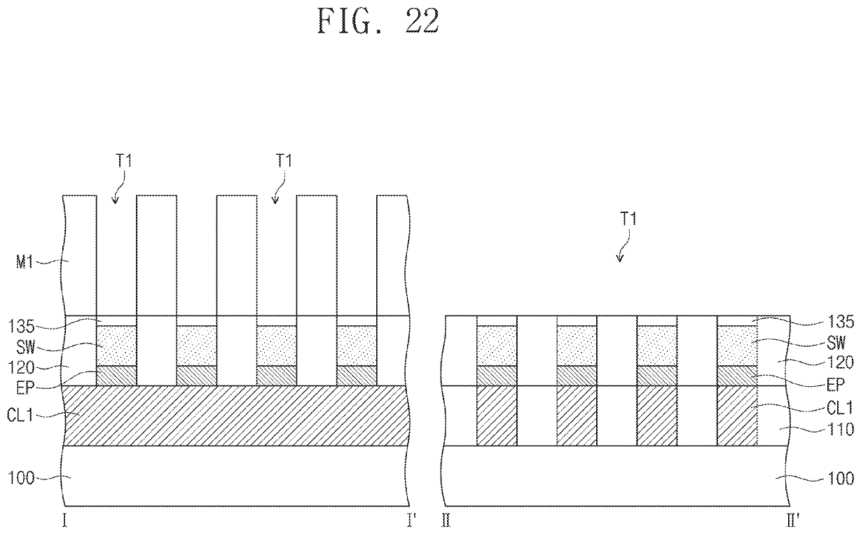

FIGS. 22 to 24 are cross-sectional views corresponding to lines I-I′ and II-IF of FIG. 3, and illustrate a method of manufacturing a variable resistance memory device according to exemplary embodiments of the present inventive concept. Hereinafter, for convenience of explanation, differences between the exemplary embodiments described herein and the exemplary embodiments previously described with reference to FIGS. 7 to 14 will be mainly described, and a further description of elements and technical features previously described may be omitted.

Referring to FIGS. 3 and 22, the first conductive lines CL1 and the first interlayer insulating layer 110 covering the first conductive lines CL1 may be formed on the substrate 100. According to exemplary embodiments, the switching patterns SW may be formed on the first conductive lines CL1. Each of the switching patterns SW may be formed on a corresponding one of the first conductive lines CL1, and each of the connection electrodes EP may be formed between each of the switching patterns SW and the corresponding first conductive line CL1. The barrier patterns 135 may be formed on the switching patterns SW, respectively. In exemplary embodiments, the formation of the barrier patterns 135, the switching patterns SW and the connection electrodes EP may include sequentially forming a connection electrode layer, a switching layer, and a barrier layer on the first interlayer insulating layer 110 and the first conductive lines CL1, and sequentially etching the barrier layer, the switching layer, and the connection electrode layer. The second interlayer insulating layer 120 may be formed on the first interlayer insulating layer 110 after the formation of the barrier patterns 135, the switching patterns SW, and the connection electrodes EP. The second interlayer insulating layer 120 may be formed to cover the barrier patterns 135, the switching patterns SW, and the connection electrodes EP.

The first mold layer M1 may be formed on the second interlayer insulating layer 120, and the first trenches T1 may be formed in the first mold layer M1. The first trenches T1 may be formed to intersect the first conductive lines CL1. Each of the first trenches T1 may expose top surfaces of the barrier patterns 135 and portions of a top surface of the second interlayer insulating layer 120, which are alternately arranged in the second direction D2.

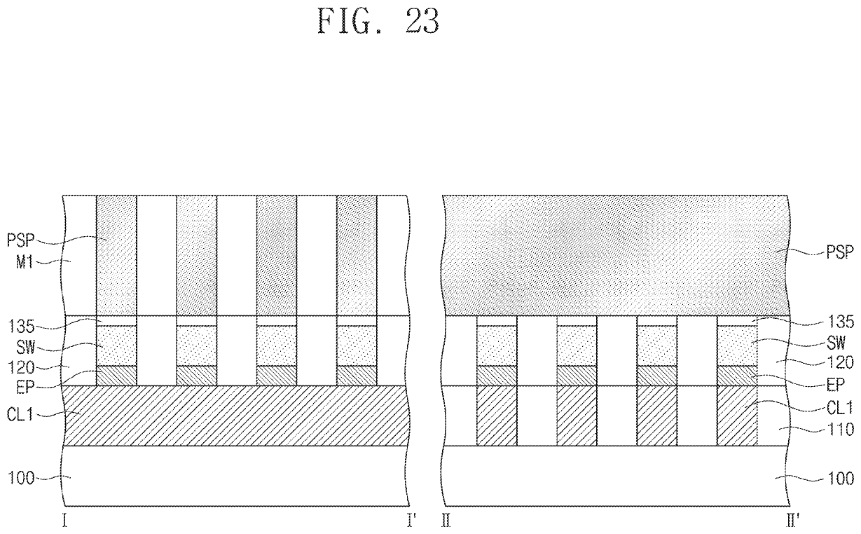

Referring to FIGS. 3 and 23, the preliminary sacrificial patterns PSP may be formed in the first trenches T1, respectively. The preliminary sacrificial patterns PSP may fill the first trenches T1, respectively. The preliminary sacrificial patterns PSP may extend in the second direction D2 and may be spaced apart from one another in the first direction D1.

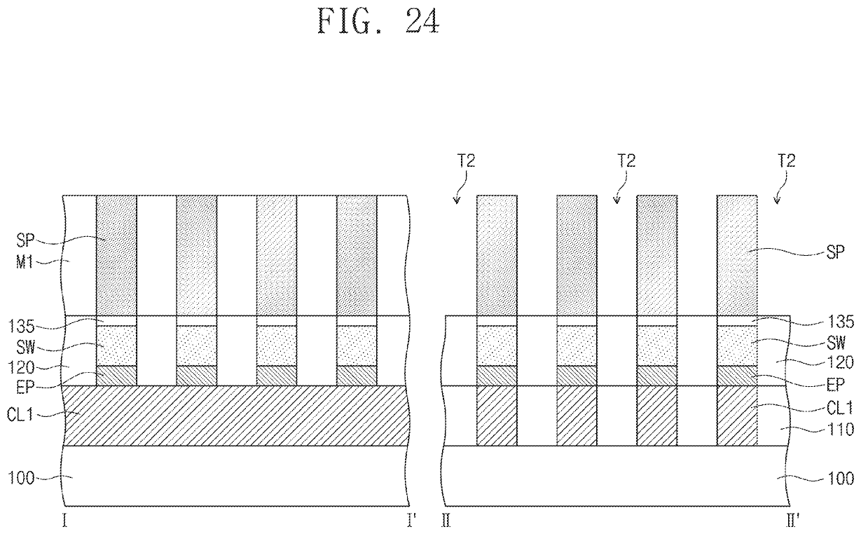

Referring to FIGS. 3 and 24, the second trenches T2 may be formed in the first mold layer M1. The second trenches T2 may be formed to intersect the first trenches T1. The formation of the second trenches T2 may include patterning the first mold layer M1 and the preliminary sacrificial patterns PSP. Each of the second trenches T2 may expose the top surface of the second interlayer insulating layer 120 between the barrier patterns 135. As a result of forming the second trenches T2, each of the preliminary sacrificial patterns PSP may be divided into the plurality of sacrificial patterns SP spaced apart from one another in the second direction D2. The sacrificial patterns SP may be formed on the barrier patterns 135, respectively. Subsequent processes may be substantially the same as the processes described above with reference to FIGS. 3 and 10 to 14.

Referring again to FIGS. 3 and 21, after the formation of the variable resistance pattern VR, the heater electrode HE, the insulating pattern 130, the third interlayer insulating layer 140, and the second conductive lines CL2 may be formed on the third interlayer insulating layer 140. The second conductive lines CL2 may be formed to intersect the first conductive lines CL1.

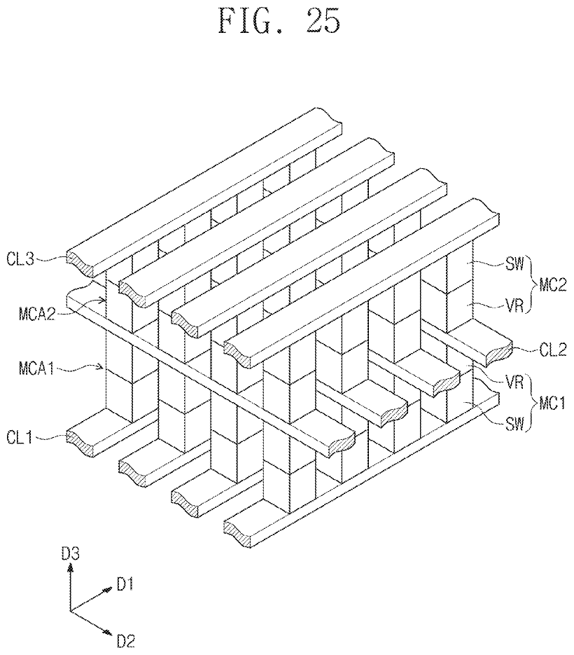

FIG. 25 is a perspective view schematically illustrating a variable resistance memory device according to exemplary embodiments of the present inventive concept. FIG. 25 illustrates two memory cell stacks MCA1 and MCA2 as an example. However, exemplary embodiments of the present inventive concept are not limited thereto. For example, in exemplary embodiments, more than two memory cell stacks MCA may be stacked on one another.

Referring to FIG. 25, first conductive lines CL1, second conductive lines CL2 and third conductive lines CL3 may be provided. The first conductive lines CL1 may extend in a first direction D1, the second conductive lines CL2 may extend in a second direction D2 intersecting the first direction D1, and the third conductive lines CL3 may extend in the first direction D1. The second conductive lines CL2 may be spaced apart from the first conductive lines CL1 in a third direction D3 substantially perpendicular to the first and second directions D1 and D2, and the third conductive lines CL3 may be spaced apart from the second conductive lines CL2 in the third direction D3.

A first memory cell stack MCA1 may be provided between the first conductive lines CL1 and the second conductive lines CL2, and a second memory cell stack MCA2 may be provided between the second conductive lines CL2 and the third conductive lines CL3. The first memory cell stack MCA1 may include first memory cells MC1 that are provided at intersecting points of the first conductive lines CL1 and the second conductive lines CL2, respectively. The first memory cells MC1 may be two-dimensionally arranged to constitute rows and columns. The second memory cell stack MCA2 may include second memory cells MC2 that are provided at intersecting points of the second conductive lines CL2 and the third conductive lines CL3, respectively. The second memory cells MC2 may be two-dimensionally arranged to constitute rows and columns.

Each of the first and second memory cells MC1 and MC2 may include a variable resistance pattern VR and a switching pattern SW. The variable resistance pattern VR and the switching pattern SW included in each of the first memory cells MC1 may be connected in series between a corresponding one of the first conductive lines CL1 and a corresponding one of the second conductive lines CL2, and the variable resistance pattern VR and the switching pattern SW included in each of the second memory cells MC2 may be connected in series between a corresponding one of the second conductive lines CL2 and a corresponding one of the third conductive lines CL3. In exemplary embodiments, the variable resistance pattern VR in each of the first memory cells MC1 may be disposed between the switching pattern SW and the corresponding second conductive line CL2, and the variable resistance pattern VR in each of the second memory cells MC2 may be disposed between the switching pattern SW and the corresponding second conductive line CL2. In exemplary embodiments, unlike FIG. 25, the switching pattern SW in each of the first memory cells MC1 may be disposed between the variable resistance pattern VR and the corresponding second conductive line CL2, and the switching pattern SW in each of the second memory cells MC2 may be disposed between the variable resistance pattern VR and the corresponding second conductive line CL2. The corresponding second conductive line CL2 may function as a common bit line.

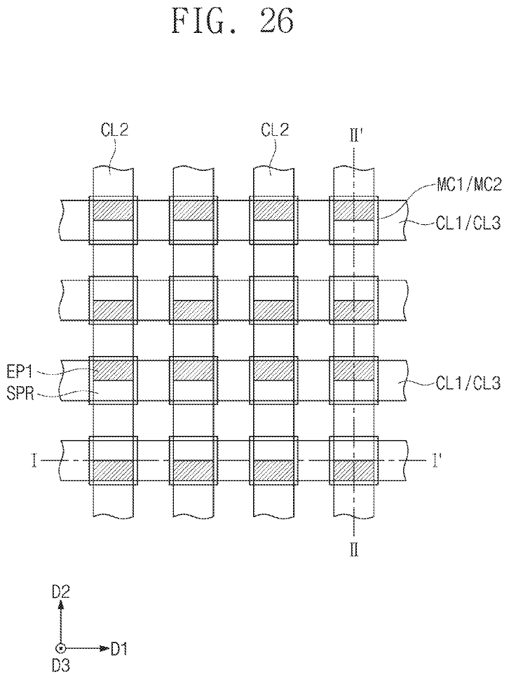

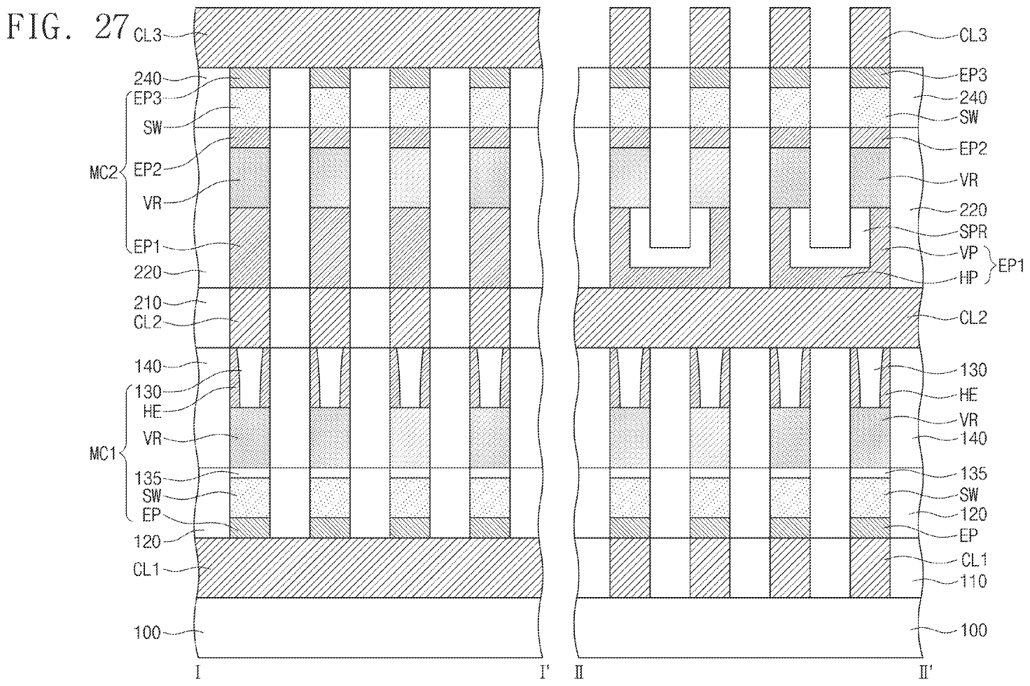

FIG. 26 is a plan view illustrating a variable resistance memory device according to exemplary embodiments of the present inventive concept. FIG. 27 is a cross-sectional view taken along lines I-I′ and II-IF of FIG. 26.

Referring to FIGS. 26 and 27, first conductive lines CL1 and second conductive lines CL2 intersecting the first conductive lines CL1 may be disposed on a substrate 100. First memory cells MC1 may be disposed between the first conductive lines CL1 and the second conductive lines CL2, and may be located at intersecting points of the first conductive lines CL1 and the second conductive lines CL2, respectively. The first conductive lines CL1, the second conductive lines CL2, and the first memory cells MC1 may be substantially the same as the first conductive lines CL1, the second conductive lines CL2, and the memory cells MC described with reference to FIGS. 3 and 21.

A fourth interlayer insulating layer 210 may be disposed on the third interlayer insulating layer 140 described with reference to FIGS. 3 and 21, and may cover the second conductive lines CL2. The fourth interlayer insulating layer 210 may expose top surfaces of the second conductive lines CL2. The fourth interlayer insulating layer 210 may include at least one of, for example, silicon oxide, silicon nitride, or silicon oxynitride.

Third conductive lines CL3 may intersect the second conductive lines CL2. The third conductive lines CL3 may extend in the first direction D1 and may be spaced apart from one another in the second direction D2. The third conductive lines CL3 may be spaced apart from the second conductive lines CL2 in the third direction D3. The third conductive lines CL3 may include a metal (e.g., copper, tungsten, or aluminum) and/or a metal nitride (e.g., tantalum nitride, titanium nitride, or tungsten nitride).

Second memory cells MC2 may be disposed between the second conductive lines CL2 and the third conductive lines CL3, and may be located at intersecting points of the second conductive lines CL2 and the third conductive lines CL3, respectively. Each of the second memory cells MC2 may be provided between a corresponding one of the second conductive lines CL2 and a corresponding one of the third conductive lines CL3. Each of the second memory cells MC2 may include a variable resistance pattern VR and a switching pattern SW, which are connected in series between the corresponding second conductive line CL2 and the corresponding third conductive line CL3. The variable resistance pattern VR and the switching pattern SW of each of the second memory cells MC2 may include the same materials as the variable resistance pattern VR and the switching pattern SW of each of the first memory cells MC1, respectively.

Each of the second memory cells MC2 may include an intermediate electrode EP2 disposed between the variable resistance pattern VR and the switching pattern SW. The intermediate electrode EP2 may electrically connect the variable resistance pattern VR and the switching pattern SW and may prevent the variable resistance pattern VR from being in direct contact with the switching pattern SW. The intermediate electrode EP2 may include, for example, at least one of W, Ti, Al, Cu, C, CN, TiN, TiAlN, TiSiN, TiCN, WN, CoSiN, WSiN, TaN, TaCN, or TaSiN. Each of the second memory cells MC2 may include an upper electrode EP3 provided between the switching pattern SW and the corresponding third conductive line CL3. The switching pattern SW may be electrically connected to the corresponding third conductive line CL3 through the upper electrode EP3. The upper electrode EP3 may be spaced apart from the intermediate electrode EP2 with the switching pattern SW interposed therebetween. The upper electrode EP3 may include, for example, at least one of W, Ti, Al, Cu, C, CN, TiN, TiAlN, TiSiN, TiCN, WN, CoSiN, WSiN, TaN, TaCN, TaSiN, or TiO.

Each of the second memory cells MC2 may include a lower electrode EP1 disposed between the variable resistance pattern VR and the corresponding second conductive line CL2. The lower electrode EP1 may be spaced apart from the intermediate electrode EP2 with the variable resistance pattern VR interposed therebetween. A pair of the second memory cells MC2 disposed adjacent to each other in the second direction D2 may share the lower electrode EP1. For example, the variable resistance patterns VR in the pair of second memory cells MC2 may be connected in common to the corresponding second conductive line CL2 through one lower electrode EP1. The lower electrode EP1 may include vertical portions VP connected to the variable resistance patterns VR in the pair of second memory cells MC2, respectively, and a horizontal portion HP extending along a top surface of the corresponding second conductive line CL2 between the vertical portions VP. The horizontal portion HP may connect the vertical portions VP to each other. The lower electrode EP1 may have a U-shape when viewed in a cross-sectional view. The lower electrode EP1 may function as a heating element that heats the variable resistance pattern VR to change a phase of the variable resistance pattern VR. The lower electrode EP1 may include, for example, at least one of W, Ti, Al, Cu, C, CN, TiN, TiAlN, TiSiN, TiCN, WN, CoSiN, WSiN, TaN, TaCN, TaSiN, or TiO.

A spacer SPR may be provided between the vertical portions VP of the lower electrode EP1. The spacer SPR may be provided on sidewalls, which face each other, of the vertical portions VP, and may extend along a top surface of the horizontal portion HP. The spacer SPR may have a U-shape when viewed in a cross-sectional view. The horizontal portion HP may extend between the spacer SPR and the top surface of the corresponding second conductive line CL2. The spacer SPR may include, for example, poly-crystalline silicon or silicon oxide.

A fifth interlayer insulating layer 220 and a sixth interlayer insulating layer 240 may be sequentially stacked on the fourth interlayer insulating layer 210. The fifth interlayer insulating layer 220 may cover the lower electrode EP1, the spacer SPR, the variable resistance pattern VR, and the intermediate electrode EP2 of each of the second memory cells MC2, and the sixth interlayer insulating layer 240 may cover the switching pattern SW and the upper electrode EP3 of each of the second memory cells MC2. The fifth and sixth interlayer insulating layers 220 and 240 may include, for example, at least one of silicon oxide, silicon nitride, or silicon oxynitride. The third conductive lines CL3 may be disposed on the sixth interlayer insulating layer 240.

Each of the second conductive lines CL2 may be connected in common to the first memory cell MC1 and the second memory cell MC2, which correspond thereto. Each of the second conductive lines CL2 may function as a common bit line. According to exemplary embodiments of the present inventive concept, each of the second memory cells MC2 and each of the first memory cells MC1 may be asymmetrical with respect to the corresponding second conductive line CL2. For example, the heater electrode HE of each of the first memory cells MC1 and the lower electrode EP1 of each of the second memory cells MC2 may perform the same function (e.g., the heater function for heating the variable resistance pattern VR), but may have different structures (or shapes) from each other.

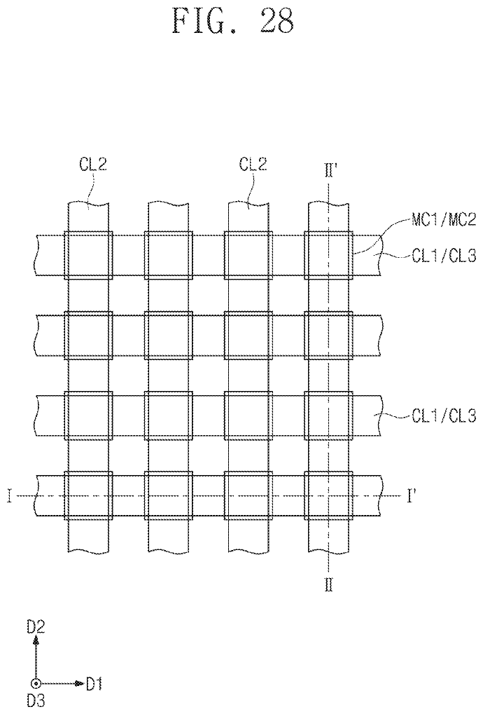

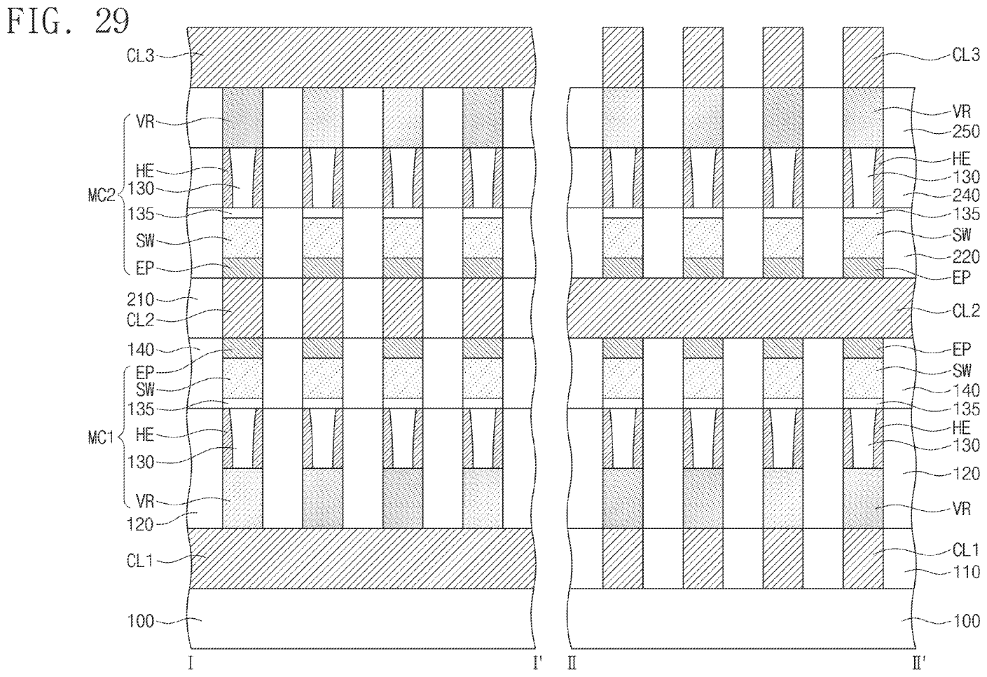

FIG. 28 is a plan view illustrating a variable resistance memory device according to exemplary embodiments of the present inventive concept. FIG. 29 is a cross-sectional view taken along lines I-I′ and II-IF of FIG. 28.

Referring to FIGS. 28 and 29, first conductive lines CL1 and second conductive lines CL2 intersecting the first conductive lines CL1 may be disposed on a substrate 100. First memory cells MC1 may be disposed between the first conductive lines CL1 and the second conductive lines CL2, and may be located at intersecting points of the first conductive lines CL1 and the second conductive lines CL2, respectively. The first conductive lines CL1, the second conductive lines CL2, and the first memory cells MC1 may be substantially the same as the first conductive lines CL1, the second conductive lines CL2, and the memory cells MC, described above with reference to FIGS. 3, 4, 5A, 5B, 6A and 6B.

A fourth interlayer insulating layer 210 may be disposed on the third interlayer insulating layer 140 described above with reference to FIGS. 3 and 4, and may cover the second conductive lines CL2. The fourth interlayer insulating layer 210 may expose top surfaces of the second conductive lines CL2. The fourth interlayer insulating layer 210 may include, for example, at least one of silicon oxide, silicon nitride, or silicon oxynitride.

Third conductive lines CL3 may intersect the second conductive lines CL2. The third conductive lines CL3 may extend in the first direction D1 and may be spaced apart from one another in the second direction D2. The third conductive lines CL3 may be spaced apart from the second conductive lines CL2 in the third direction D3. The third conductive lines CL3 may include a metal (e.g., copper, tungsten, or aluminum) and/or a metal nitride (e.g., tantalum nitride, titanium nitride, or tungsten nitride).

Second memory cells MC2 may be disposed between the second conductive lines CL2 and the third conductive lines CL3, and may be located at intersecting points of the second conductive lines CL2 and the third conductive lines CL3, respectively. Each of the second memory cells MC2 may be provided between a corresponding one of the second conductive lines CL2 and a corresponding one of the third conductive lines CL3. Each of the second memory cells MC2 may include a variable resistance pattern VR and a switching pattern SW, which are connected in series between the corresponding second conductive line CL2 and the corresponding third conductive line CL3. Each of the second memory cells MC2 may further include a connection electrode EP disposed between the switching pattern SW and the corresponding second conductive line CL2, a heater electrode HE disposed between the switching pattern SW and the variable resistance pattern VR, an insulating pattern 130 filling an inside of the heater electrode HE, and a barrier pattern 135 disposed between the switching pattern SW and the heater electrode HE and between the switching pattern SW and the insulating pattern 130. Except for relative positions of the connection electrode EP, the switching pattern SW, the barrier pattern 135, the heater electrode HE, the insulating pattern 130, and the variable resistance pattern VR, other features of each of the second memory cells MC2 may be substantially the same as corresponding features of the memory cell MC described above with reference to FIGS. 3, 4, 5A, 5B, 6A and 6B.

A fifth interlayer insulating layer 220, a sixth interlayer insulating layer 240 and a seventh interlayer insulating layer 250 may be sequentially stacked on the fourth interlayer insulating layer 210. The fifth interlayer insulating layer 220 may cover the connection electrode EP, the switching pattern SW and the barrier pattern 135 of each of the second memory cells MC2. The heater electrode HE and the insulating pattern 130 of each of the second memory cells MC2 may be disposed in the sixth interlayer insulating layer 240, and the variable resistance pattern VR of each of the second memory cells MC2 may be disposed in the seventh interlayer insulating layer 250. The fifth to seventh interlayer insulating layers 220, 240 and 250 may include, for example, at least one of silicon oxide, silicon nitride, or silicon oxynitride. The third conductive lines CL3 may be disposed on the seventh interlayer insulating layer 250.

Each of the second conductive lines CL2 may be connected in common to the first memory cell MC1 and the second memory cell MC2, which correspond thereto. Each of the second conductive lines CL2 may function as a common bit line. According to exemplary embodiments of the present inventive concept, each of the second memory cells MC2 and each of the first memory cells MC1 may be symmetrical with respect to the corresponding second conductive line CL2. For example, the heater electrode HE of each of the first memory cells MC1 and the heater electrode HE of each of the second memory cells MC2 may perform the same function and may have substantially the same structure (or shape).

According to exemplary embodiments of the present inventive concept, the heater electrode HE may prevent the switching pattern SW from being in direct contact with the variable resistance pattern VR, and may also function as a heating element that heats the variable resistance pattern VR for the phase change of the variable resistance pattern VR. In this case, in exemplary embodiments, the memory cell MC does not include an additional electrode for heating the variable resistance pattern VR. Thus, the structure of the memory cell MC may be simplified. In addition, since the structure of the memory cell MC is simplified, the processes for forming the memory cell MC may also be efficiently performed.

As a result, exemplary embodiments provide a variable resistance memory device including a memory cell having the simplified structure described above, and provides an efficient method of manufacturing the same.

While the present inventive concept has been particularly shown and described with reference to the exemplary embodiments thereof, it will be apparent to those skilled in the art that various changes in form and detail may be made therein without departing from the spirit and scope of the present inventive concept as defined by the following claims.

1. A variable resistance memory device, comprising:
a first conductive line disposed on a substrate;
a second conductive line disposed on the first conductive line and intersecting the first conductive line; and
a memory cell disposed between the first conductive line and the second conductive line,
wherein the memory cell comprises:
a variable resistance pattern; and
a heater electrode disposed on the variable resistance pattern,
wherein the heater electrode comprises a through-hole penetrating the heater electrode, and the through-hole exposes one surface of the variable resistance pattern.

2. The variable resistance memory device of claim 1, wherein the memory cell further comprises:
an insulating pattern disposed on the variable resistance pattern, wherein the insulating pattern is disposed in the through-hole of the heater electrode.

3. The variable resistance memory device of claim 2, wherein the heater electrode surrounds a sidewall of the insulating pattern.

4. The variable resistance memory device of claim 3, wherein the heater electrode has a ring shape when viewed in a plan view.

5. The variable resistance memory device of claim 1, wherein an outer sidewall of the heater electrode is substantially aligned with a sidewall of the variable resistance pattern.

6. The variable resistance memory device of claim 1, wherein the memory cell further comprises;
a switching pattern connected in series to the variable resistance pattern and the heater electrode.

7. The variable resistance memory device of claim 6, wherein the heater electrode is disposed between the variable resistance pattern and the switching pattern.

8. The variable resistance memory device of claim 7, wherein the variable resistance pattern is disposed between the first conductive line and the heater electrode, and the switching pattern is disposed between the second conductive line and the heater electrode.

9. The variable resistance memory device of claim 7, wherein the memory cell further comprises:
a barrier pattern disposed between the heater electrode and the switching pattern, wherein the barrier pattern comprises carbon.

10. The variable resistance memory device of claim 1, wherein the heater electrode is spaced apart from the first conductive line, the variable resistance pattern is disposed between the heater electrode and the first conductive line, and the variable resistance pattern is in contact with the first conductive line.

11. A variable resistance memory device, comprising:
a first conductive line disposed on a substrate and extending in a first direction;
a second conductive line disposed on the first conductive line and extending in a second direction intersecting the first direction; and
a memory cell disposed between the first conductive line and the second conductive line and located at an intersecting point of the first conductive line and the second conductive line,
wherein the memory cell comprises:
a variable resistance pattern;
an insulating pattern disposed on a top surface of the variable resistance pattern; and
a heater electrode disposed on the top surface of the variable resistance pattern and surrounding a sidewall of the insulating pattern.

12. The variable resistance memory device of claim 11, wherein an inner sidewall of the heater electrode is in contact with the insulating pattern, and an outer sidewall of the heater electrode is substantially aligned with a sidewall of the variable resistance pattern.

13. The variable resistance memory device of claim 11, wherein the memory cell further comprises:
a switching pattern,
wherein the insulating pattern and the heater electrode are disposed between the variable resistance pattern and the switching pattern.

14. The variable resistance memory device of claim 11, wherein the insulating pattern and the heater electrode are in contact with the top surface of the variable resistance pattern.

15. The variable resistance memory device of claim 14, wherein the first conductive line is in contact with a bottom surface of the variable resistance pattern.

16. The variable resistance memory device of claim 11, wherein the insulating pattern has a pillar shape which extends from the top surface of the variable resistance pattern in a third direction substantially perpendicular to a top surface of the substrate, and the heater electrode has a pipe shape which extends from the top surface of the variable resistance pattern in the third direction.

17. The variable resistance memory device of claim 11, wherein the heater electrode has an opened top end and an opened bottom end.

18. A variable resistance memory device, comprising:
a plurality of first conductive lines disposed on a substrate and extending in a first direction;
a plurality of second conductive lines disposed on the first conductive lines and extending in a second direction intersecting the first direction; and
a plurality of memory cells disposed between the first conductive lines and the second conductive lines, and disposed at intersecting points of the first conductive lines and the second conductive lines, respectively,
wherein each of the memory cells comprises:
a variable resistance pattern; and
a heater electrode disposed on a top surface of the variable resistance pattern,
wherein the heater electrode has a pipe shape which extends from the top surface of the variable resistance pattern in a third direction substantially perpendicular to a top surface of the substrate.

19. The variable resistance memory device of claim 18, wherein the heater electrode has a pipe shape comprising an opened top end and an opened bottom end.

20. The variable resistance memory device of claim 19, wherein each of the memory cells further comprises:
an insulating pattern disposed on the top surface of the variable resistance pattern, wherein the insulating pattern fills an inside of the heater electrode.

21-25. (canceled)
